(19) United States
(12) Patent Application Publication
(10) Pub. No.: US 2026/0239746 A1
(43) Pub. Date: Aug. 13, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Lin-Yu HUANG, Hsinchu (TW); Shih-Fan CHEN, Hsinchu City (TW); Sheng-Fu HSU, Hsinchu (TW)

(21) Appl. No.: 19/048,627

(22) Filed: Feb. 7, 2025

(51) Int. Cl. H10D 89/60; H10D 10/01; H10D 62/10

(52) U.S. Cl. CPC H10D 89/711; H10D 10/061; H10D 62/115; H10D 89/611

(57) ABSTRACT

A semiconductor device includes a high voltage electrostatic discharge (ESD) triggering device that includes a combination of isolation regions (e.g., shallow trench isolation (STI) regions), and resist protective oxide (RPO) structures over doped regions of a substrate. The RPO structures partially overlap STI regions in areas between doped collectors and doped emitters of a high voltage ESD triggering device. The STI regions which are partially overlapped by the RPO structures have widths that allow for unobstructed movement of charge carriers (e.g., holes) from areas between the doped collectors and doped emitters to the doped collectors. As a result, on-resistance (Rₒₙ) is reduced in comparison to the Rₒₙ for high voltage ESD triggering devices with other isolation region arrangements. Additionally, breakdown voltage is preserved, leading to increased operating efficiency and performance for high voltage ESD triggering devices including the isolation region and RPO structure arrangements.

### BACKGROUND

Electrostatic discharge (ESD) is a concern for semiconductor integrated circuits (ICs). If not handled properly, an ESD event can result in a high voltage that may damage device circuitry of a semiconductor device. To prevent ESD-related damage, a semiconductor device may include an ESD protection circuit. The ESD protection circuit may be operable to divert electrical current away from device circuitry of the semiconductor device during an ESD event, thereby protecting the device circuitry from being damaged by the ESD event.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are diagrams of example semiconductor devices described herein.

FIGS. 2A and 2B are diagrams of example implementations of an electrostatic discharge (ESD) triggering circuit described herein.

FIGS. 3A-3J are diagrams of an example implementation of forming an ESD triggering circuit in a semiconductor device described herein.

FIG. 4 is a diagram of an example implementation of an ESD triggering circuit described herein.

FIGS. 5A-5C are diagrams of an example implementation of forming an ESD triggering circuit in a semiconductor device described herein.

FIG. 6 is a diagram of an example implementation of an ESD triggering circuit described herein.

FIGS. 7A and 7B are diagrams of example implementations of an ESD triggering circuit described herein.

FIG. 8 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An electrostatic discharge (ESD) protection device may be included between regions of a semiconductor device to provide ESD protection for ESD events that might otherwise propagate between the regions of the semiconductor device. For example, an ESD protection device may be included between an input/output (I/O) region and a core integrated circuit (IC) region to protect the core IC region from ESD events that enter the semiconductor device through the I/O region.

Some semiconductor devices include high voltage circuits that are configured to operate at high voltages (e.g., greater than 40 volts, for example). In some cases, ESD protection circuits may be triggered by ESD triggering circuitry that is unable to handle the high voltages of these high voltage circuits and may prematurely trigger ESD protection during normal operation for these high voltage circuits, thereby rendering the high voltage circuits inoperable. As a result, high voltage ESD triggering devices are needed for high voltage circuit applications. A high voltage ESD triggering device may trigger the operation of an ESD protection circuit based on the voltage applied to the high voltage ESD triggering device satisfying a breakdown voltage (BV) of the high voltage ESD triggering device. High BV could be achieved by incorporating dielectric isolation regions into the high voltage ESD triggering device. However, the isolation regions may cause high on resistance (Rₒₙ) for an ESD triggering circuit, which may lead to reduced operating efficiency for the ESD triggering circuit, or failure of ESD devices and functional devices during ESD events. The high Rₒₙ may be caused by isolation regions blocking movement of electrons and holes between doped regions.

In some implementations described herein, a semiconductor device includes a high voltage ESD triggering device that includes a combination of isolation regions (e.g., shallow trench isolation (STI) regions), and resist protective oxide (RPO) structures over doped regions of a substrate. The RPO structures partially overlap STI regions in areas between doped collectors and doped emitters of a high voltage ESD triggering device. The STI regions which are partially overlapped by the RPO structures have smaller widths than STI regions that are not overlapped by the RPO structures. The smaller dimensions allow for unobstructed movement of charge carriers (e.g., holes) from areas between the doped collectors and doped emitters to the doped collectors. As a result, Rₒₙ is reduced in comparison to the Rₒₙ for high voltage ESD triggering devices with other isolation region arrangements. Additionally, the inclusion of the combination of isolation regions preserves BV, leading to increased operating efficiency and performance for high voltage ESD triggering devices including the noted isolation region and RPO structure arrangements.

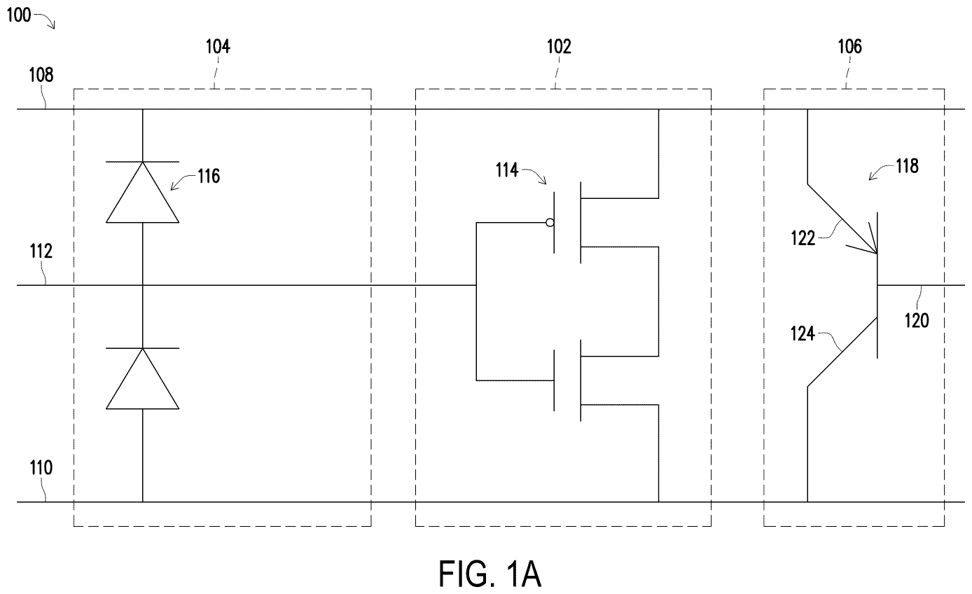

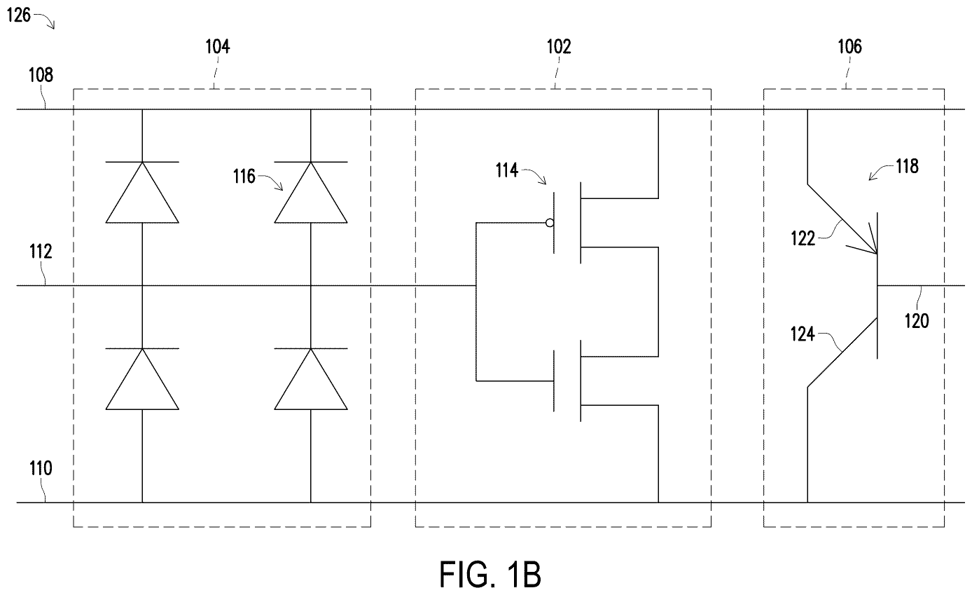

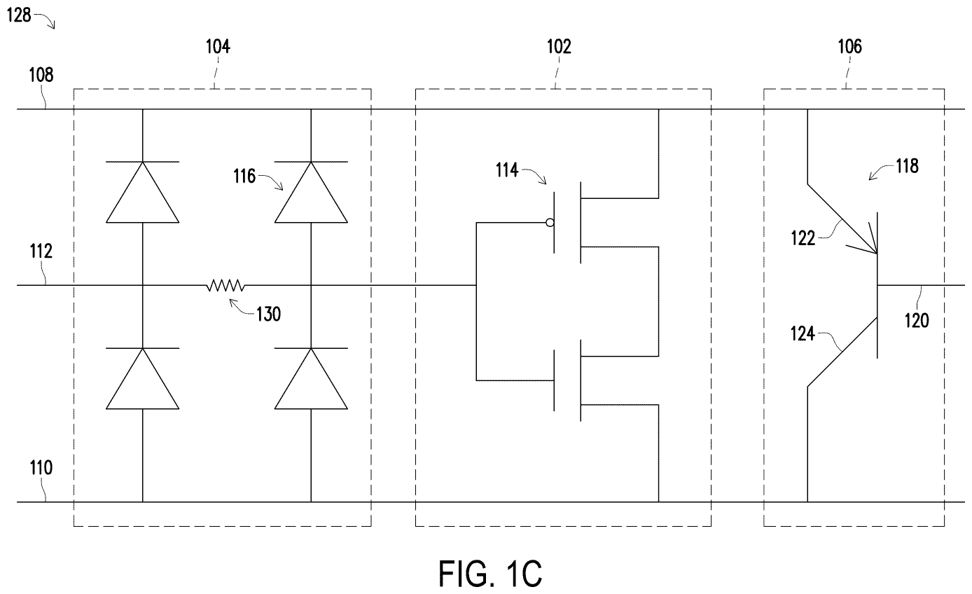

FIGS. 1A-1C are diagrams of example semiconductor devices described herein. The semiconductor device 100 may include a logic device (e.g., a processor, a central processing unit (CPU), a graphics processing unit (GPU)), a memory device (e.g., a dynamic random access memory (DRAM) device, a static random access memory (SRAM) device), a display panel device (e.g., a display panel driver including a driver integrated circuit (IC), a line driver IC, a level shifter IC), and/or another type of semiconductor device 100 that includes high voltage semiconductor devices.

As shown in FIG. 1A, an example semiconductor device 100 may include a device circuit 102, an ESD protection circuit 104, and an ESD triggering circuit 106, among other types of circuits. The device circuit 102, the ESD protection circuit 104, and/or the ESD triggering circuit 106 may be coupled with a drain input 108, a source input 110, and/or a control input 112, among other examples.

The device circuit 102 may include one or more transistors 114. The one or more transistors may be configured to perform logic operations, memory operations, power supply operations, analog-to-digital conversion operations, and/or other types of semiconductor device operations. In some implementations, the transistors 114 may be configured as complementary metal oxide semiconductor (CMOS) logic circuitry or another type of circuitry. In some implementations, the device circuit 102 includes a high voltage device circuit, and the transistors 114 include high voltage transistors. A high voltage transistor may include a high voltage planar transistor, a high voltage fin field effect transistor (finFET), a high voltage nanostructure (e.g., a gate all around (GAA) transistor, a nanowire transistor, a nanosheet transistor, a multi-bridge channel transistor, a nanoribbon transistor), and/or another type of high voltage transistor that is configured to operate at high voltages (e.g., greater than 40 volts, for example).

The ESD protection circuit 104 may include one or more ESD protection devices 116 that are configured to provide ESD protection for the device circuit 102 against high voltage spikes, high voltage surges, and/or other types of high voltage events. For example, the ESD protection circuit 104 may include one or more diodes and/or one or more of another type of ESD protection device that are configured to provide ESD protection for the device circuit 102 against high voltage spikes, high voltage surges, and/or other types of high voltage events. As shown in FIG. 1A, in the example semiconductor device 100, the ESD protection devices 116 may be connected in series with each other, and the ESD protection devices 116 may be connected to the drain input 108, the source input 110, and the control input 112.

The ESD triggering circuit 106 may include one or more PNP ESD triggering devices 118. A PNP ESD triggering device 118 may be configured to redirect electrical current away from the device circuit 102 and toward the ESD protection circuit 104 based on or in response to a high voltage event so that the ESD protection circuit 104 can discharge the electrical current, thereby protecting the device circuit 102. The PNP ESD triggering device 118 may include a bipolar junction transistor (BJT) that is configured to trigger activation of the ESD protection circuit 104 based on a voltage for the device circuit 102 satisfying a threshold voltage. The threshold voltage may be greater relative to the operating voltage of the device circuit 102. For example, if the device circuit 102 operates at approximately 40 volts, the threshold voltage may be included in a range of approximately 50 volts to approximately 65 volts. However, other values for the range are within the scope of the present disclosure. The PNP ESD triggering device 118 may include an n-doped base 120, a p-doped emitter 122, and a p-doped collector 124, thereby forming the PNP structure of the PNP ESD triggering device 118.

FIG. 1B illustrates another example semiconductor device 126. As shown in FIG. 1B, the semiconductor device 126 may include a similar configuration of circuits as the semiconductor device 100. For example, the semiconductor device 126 may include a device circuit 102, an ESD protection circuit 104, and an ESD triggering circuit 106. The device circuit 102 may include one or more transistors 114, the ESD protection circuit 104 may include a plurality of ESD protection devices 116, and the ESD triggering circuit 106 may include one or more PNP ESD triggering devices 118. As further shown in FIG. 1B, the ESD protection circuit 104 may include a plurality of pairs of ESD protection devices 116 that are connected in parallel in the ESD protection circuit 104. The ESD protection devices 116 may be connected in series with each other, and the ESD protection devices 116 may be connected to the drain input 108, the source input 110, and the control input 112.

FIG. 1C illustrates another example semiconductor device 128. As shown in FIG. 1C, the semiconductor device 128 may include a similar configuration of circuits as the semiconductor device 100 and the semiconductor device 126. For example, the semiconductor device 128 may include a device circuit 102, an ESD protection circuit 104, and an ESD triggering circuit 106. The device circuit 102 may include one or more transistors 114, the ESD protection circuit 104 may include a plurality of ESD protection devices 116, and the ESD triggering circuit 106 may include one or more PNP ESD triggering devices 118.

As further shown in FIG. 1C, the ESD protection circuit 104 may include a plurality of pairs of ESD protection devices 116 that are connected in parallel in the ESD protection circuit 104. The ESD protection devices 116 may be connected in series with each other, and the ESD protection devices 116 may be to the drain input 108, the source input 110, and the control input 112. As further shown in FIG. 1C, the ESD protection circuit 104 may include a resistor 130 that cross couples the pairs of ESD protection devices 116.

As indicated above, FIGS. 1A-1C are provided as examples. Other examples may differ from what is described with regard to FIGS. 1A-1C.

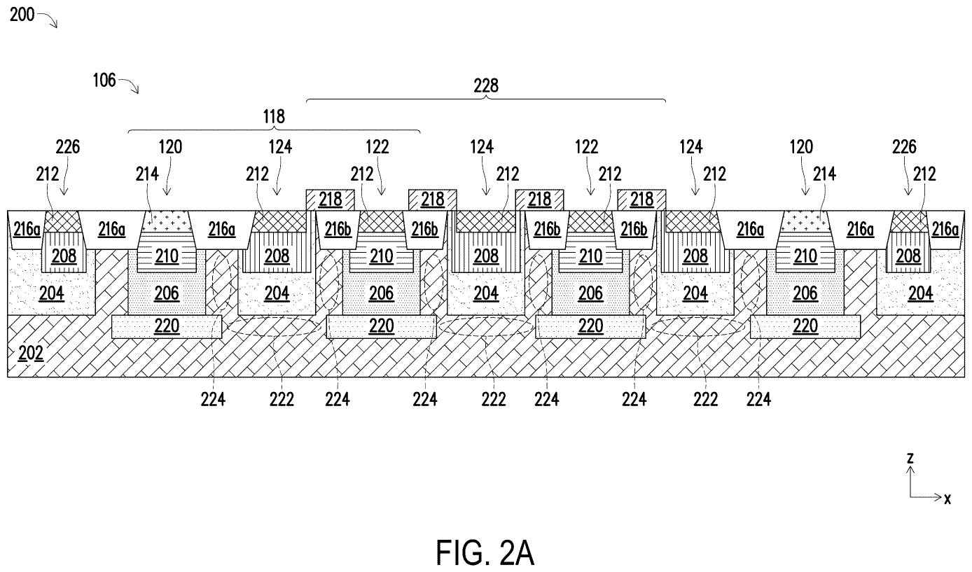

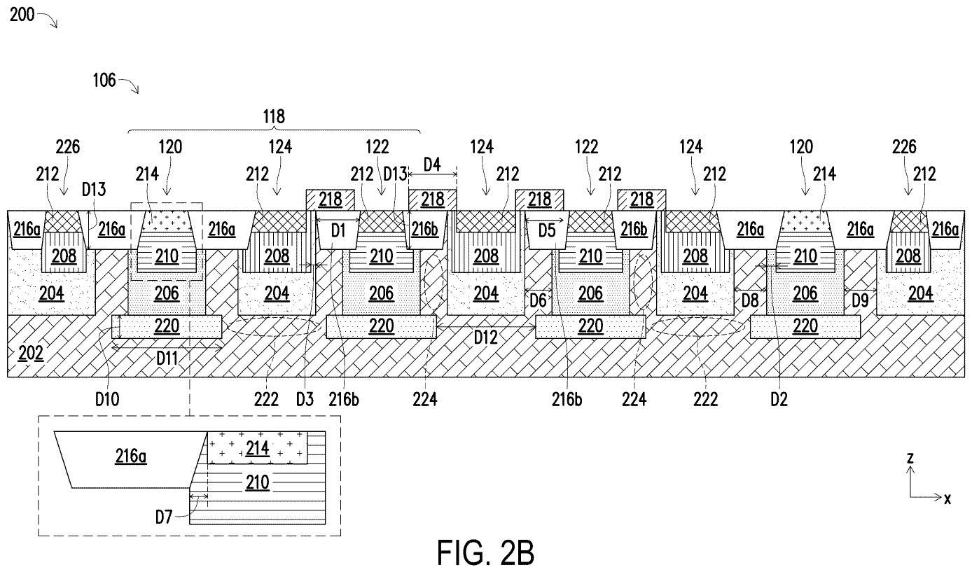

FIGS. 2A and 2B are diagrams of example implementations of an ESD triggering circuit 106 described herein. The example implementations of the ESD triggering circuit 106 described in connection with FIGS. 2A and 2B may be included in a semiconductor device, such as the semiconductor device 100, the semiconductor device 126, the semiconductor device 128, and/or another semiconductor device that includes high voltage devices.

FIGS. 2A and 2B illustrate an example implementation 200 of an ESD triggering circuit 106. As shown in FIG. 2A, the ESD triggering circuit 106 may be formed and/or included in a substrate 202 of the semiconductor device. The substrate 202 may include a silicon (Si) substrate, a substrate formed of a material including silicon, a III-V compound semiconductor material substrate such as gallium arsenide (GaAs), a silicon on insulator (SOI) substrate, a germanium (Ge) substrate, a silicon germanium (SiGe) substrate, a silicon carbide (SiC) substrate, or another type of semiconductor substrate. The substrate 202 may include various layers, including conductive or insulating layers formed on a semiconductor substrate. The substrate 202 may include a compound semiconductor and/or an alloy semiconductor. The substrate 202 may include various doping configurations to satisfy one or more design parameters. For example, different doping profiles (e.g., n-wells, p-wells) may be formed on the substrate 202 in regions designed for different device types (e.g., p-type metal-oxide semiconductor (PMOS) nanostructure transistors, n-type metal-oxide semiconductor (NMOS) nanostructure transistors). The suitable doping may include ion implantation of dopants and/or diffusion processes. Further, the substrate 202 may include an epitaxial layer (epi-layer), may be strained for performance enhancement, and/or may have other suitable enhancement features. The substrate 202 may include a portion of a semiconductor wafer on which other semiconductor devices are formed.

The ESD triggering circuit 106 may include a plurality of doped regions that are included in the substrate 202. For example, the ESD triggering circuit 106 may include a plurality of p-doped wells 204 that are included in the substrate 202. The p-doped wells 204 may be regions of the substrate 202 that are doped with one or more p-type dopants, such as boron (B), gallium (Ga), and/or indium (In), among other examples. As another example, the ESD triggering circuit 106 may include a plurality of n-doped wells 206 that are included in the substrate 202. The n-doped wells 206 may be regions of the substrate 202 that are doped with one or more n-type dopants, such as phosphorous (P), arsenic (As), bismuth (Bi), and/or antimony (Sb), among other examples. In some implementations, one or more of the p-doped wells 204 are omitted from the ESD triggering circuit 106 to reduce manufacturing cost and/or manufacturing complexity for forming the ESD triggering circuit 106. However, including the p-doped wells 204 may reduce on resistance (Rₒₙ) for the ESD triggering circuit 106. In some implementations, one or more of the n-doped wells 206 are omitted from the ESD triggering circuit 106 to reduce manufacturing cost and/or manufacturing complexity for forming the ESD triggering circuit 106. However, including the n-doped wells 206 may reduce on resistance (Rₒₙ) for the ESD triggering circuit 106.

As another example, the ESD triggering circuit 106 may include a plurality of p+ regions 208 (e.g., p-type regions) included in the substrate 202. The p+ regions 208 may be regions of the substrate 202 that are doped with one or more p-type dopants, such as boron (B), gallium (Ga), and/or indium (In), among other examples. As another example, the ESD triggering circuit 106 may include a plurality of n+ regions 210 (e.g., n-type regions) included in the substrate 202. The n+ regions 210 may be regions of the substrate 202 that are doped with one or more n-type dopants, such as phosphorous (P), arsenic (As), bismuth (Bi), and/or antimony (Sb), among other examples.

As another example, the ESD triggering circuit 106 may include a plurality of p+ regions 212 (e.g., p-type regions) included in the substrate 202. The p+ regions 212 may be regions of the substrate 202 that are doped with one or more p-type dopants, such as boron (B), gallium (Ga), and/or indium (In), among other examples. As another example, the ESD triggering circuit 106 may include a plurality of n+ regions 214 (e.g., n-type regions) included in the substrate 202. The n+ regions 214 may be regions of the substrate 202 that are doped with one or more n-type dopants, such as phosphorous (P), arsenic (As), bismuth (Bi), and/or antimony (Sb), among other examples.

The p-doped wells 204, the p+ regions 208, and the p+ regions 212 may have different dopant concentrations. For example, the dopant concentration in the p+ regions 212 may be greater relative to the dopant concentration in the p+ regions 208, and the dopant concentration in the p+ regions 208 may be greater relative to a dopant concentration in the p-doped wells 204.

The n-doped wells 206, the n+ regions 210, and the n+ regions 214 may have different dopant concentrations. For example, the dopant concentration in the n+ regions 214 may be greater relative to the dopant concentration in the n+ regions 210, and the dopant concentration in the n+ regions 210 may be greater relative to a dopant concentration in the n-doped wells 206.

As further shown in FIG. 2A, the ESD triggering circuit 106 may include one or more PNP ESD triggering devices 118. A PNP ESD triggering device 118 may include an n-doped base 120, a p-doped emitter 122, and a p-doped collector 124. In some implementations, the ESD triggering circuit 106 may include 2 to 50 “fingers” of PNP ESD triggering devices 118. For example, 2 fingers refers to 2 n-doped bases 120, 3 p-doped collectors 124, and 2 p-doped emitters 122. As another example, 3 fingers refers to 2 n-doped bases 120, 4 p-doped collectors 124, and 3 p-doped emitters 122.

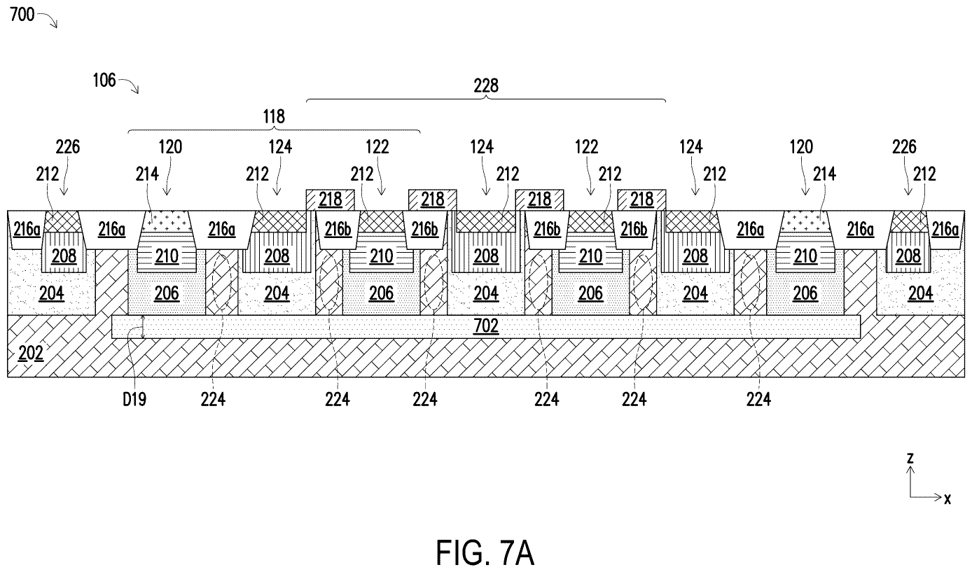

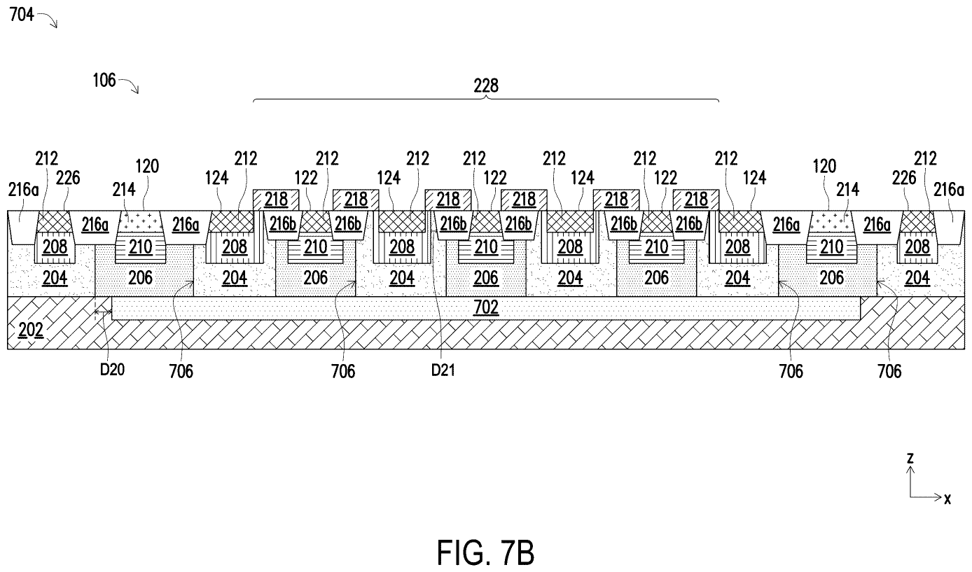

An n-doped base 120 may include an n-doped well 206, an n+ region 210 in the n-doped well 206, and an n+ region 214 in the n+ region 210. A p-doped emitter 122 may include an n-doped well 206, an n+ region 210 in the n-doped well 206, and a p+ region 212 in the n+ region 210. A p-doped collector 124 may include a p-doped well 204, a p+ region 208 in the p-doped well 204, and a p+ region 212 in the p+ region 208. In the example implementation 200 shown in FIG. 2A, the p-doped wells 204 of the p-doped collectors 124 are spaced apart from the n-doped wells 206 of the n-doped bases 120 and of the p-doped emitters 122. Portions of the substrate 202 occupy the spaces between the p-doped wells 204 and the n-doped wells 206. In some implementations, as described in more detail in connection with FIG. 7B, edges of the p-doped wells 204 may be in contact with edges of the n-doped wells 206, so that the p-doped wells 204 are not spaced apart from the n-doped wells 206. For example, as an alternative to the example implementation 200, the edges of the p-doped wells 204 may be in contact with edges of the n-doped wells 206, while other elements as shown in FIG. 2A have the same arrangement as in the example implementation 200.

As further shown in FIG. 2A, the ESD triggering circuit 106 may include a plurality of first STI regions 216a and a plurality of second STI regions 216b in the substrate 202. The first STI regions 216a have a larger dimension (e.g., width) in the x-direction than the second STI regions 216b. As can be seen in FIG. 2A, the smaller dimension in the x-direction of a second STI region 216b permits the second STI region 216b to be spaced apart from edges of the p+ region 208 and the p+ region 212 of a p-doped collector 124. In addition, given the tapered structure of the second STI regions 216b, where the width (e.g., x-direction dimension) of the second STI regions 216b decreases in a direction (e.g., z-direction) into the substrate 202, portions of outer lateral edges of the second STI regions 216b are spaced apart from edges of p-doped wells 204 of adjacent p-doped collectors 124. A portion of a space between an edge of a second STI region 216b and an edge of a p-doped well 204 is occupied by part of the substrate 202. The second STI region 216b being spaced apart from the p-doped well 204, the p+ region 208, and/or the p+ region 212 of a p-doped collector 124 allows for unobstructed movement of holes to the p-doped collector 124 from an area between the p-doped collector 124 and an adjacent p-doped emitter 122. As a result, Rₒₙ is reduced in comparison to the Rₒₙ for high voltage ESD triggering devices with other STI region arrangements.

Two second STI regions 216b on opposite sides of a p-doped emitter 122 in the x-direction are in contact with the n-doped well 206, n+ region 210, and p+ region 212 of the p-doped emitter 122. Portions of bottom sides and left or right sides of the two second STI regions 216b abut the n-doped well 206, n+ region 210, and/or p+ region 212 of the p-doped emitter 122. Each of the two second STI regions 216b may also be spaced apart from p-doped wells 204, p+ regions 208, and/or p+ regions 212 of adjacent p-doped collectors 124 on opposite sides of the p-doped emitter 122 in the x-direction. Two first STI regions 216a on opposite sides of an n-doped base 120 in the x-direction are in contact with the n-doped well 206, n+ region 210, and n+ region 214 of the n-doped base 120. Portions of bottom sides and left or right sides of the two first STI regions 216a abut the n-doped well 206, n+ region 210, and/or n+ region 214 of the n-doped base 120. In addition, a first STI region 216a contacting an n-doped base 120 may also contact a p-doped well 204, a p+ region 208, and a p+ region 212 of an adjacent p-doped collector 124 on an opposite side of the first STI region 216a. Depending on location, portions of a bottom side and of a left or right side of the first STI region 216a abut the p-doped well 204, p+ region 208, and/or p+ region 212 of the adjacent p-doped collector 124.

The first and second STI regions 216a and 216b may include a dielectric material such as a silicon oxide (SiOₓ), a silicon nitride (SiₓN_{y}), a silicon oxynitride (SiON), fluoride-doped silicate glass (FSG), a low dielectric constant (low-k) dielectric material, and/or another suitable insulating material. The first and second STI regions 216a and 216b may include a multi-layer structure, for example, having one or more liner layers.

As further shown in FIG. 2A, the ESD triggering circuit 106 may include a plurality of resist protective oxide (RPO) structures 218 over and/or on the substrate 202. For example, respective RPO structures 218 may be included over and/or on the substrate 202 between a p-doped collector 124 and an adjacent p-doped emitter 122 of a PNP ESD triggering device 118. An RPO structure 218 may include oxide material such as a silicon oxide (SiOₓ such as SiO₂) and/or another dielectric oxide material. An RPO structure 218 may be included to control the flow of charge carriers in the PNP ESD triggering device 118. In some implementations, an RPO structure 218 may partially overlap a p-doped well 204 of a p-doped collector 124, and a p+ region 208 of a p-doped collector 124, and partially overlap a second STI region 216b, where the second STI region 216b is in contact with an n-doped well 206, an n+ region 210, and a p+ region 212 of a p-doped emitter 122. A bottom and/or lateral side (e.g., left or right side) of the second STI region 216b is in contact with (e.g., abuts) an n-doped well 206, an n+ region 210, and/or a p+ region 212 of the p-doped emitter 122. An RPO structure 218 also overlaps a space between an edge of a second STI region 216b and an edge of a p-doped well 204 of an adjacent p-doped collector 124, where the space is occupied by part of the substrate 202. As can be seen, an RPO structure 218 overlaps a space between an edge of a second STI region 216b and edges of the p+ region 208 and p+ region 212 of an adjacent p-doped collector 124, where the space is occupied by parts of the p-doped well 204 and the p+ region 208.

As further shown in FIG. 2A, the ESD triggering circuit 106 may include one or more n-doped barrier regions 220 in the substrate 202. N-doped barrier regions 220 may be included under the n-doped base 120 of the PNP ESD triggering device 118 and under the p-doped emitter 122 of the PNP ESD triggering device 118. The n-doped barrier regions 220 may be included under the n-doped base 120 of the PNP ESD triggering device 118 and under the p-doped emitter 122 of the PNP ESD triggering device 118 to reduce or prevent charge carrier migration from the n-doped wells 206 into the substrate 202. The reduced or eliminated charge carrier migration into the substrate 202 may increase the operating efficiency of the ESD triggering circuit 106. The n-doped barrier regions 220 may be regions of the substrate 202 that are doped with one or more n-type dopants, such as phosphorous (P), arsenic (As), bismuth (Bi), and/or antimony (Sb), among other examples.

The n-doped barrier regions 220 may be omitted (not included) under the p-doped collector 124 of the PNP ESD triggering device 118. The omission of the n-doped barrier regions 220 under the p-doped collector 124 of the PNP ESD triggering device 118 results in gaps or portions 222 of the substrate 202 being located between the n-doped barrier regions 220. The PNP ESD triggering device 118 may trigger the operation of the ESD protection circuit 104 based on the voltage applied to the PNP ESD triggering device 118 satisfying a breakdown voltage of the PNP ESD triggering device 118. If the breakdown occurs between an n-doped barrier region 220 and the p-doped well 204 of the p-doped collector 124, the breakdown voltage of the PNP ESD triggering device 118 may be too low to accommodate the high operating voltages of the associated device circuit 102 in the semiconductor device, resulting in the device circuit 102 being unable to properly function.

The omission of the n-doped barrier regions 220 under the p-doped collector 124 of the PNP ESD triggering device 118 results in a lack of a P-N interface under the p-doped collector 124, which prevents the breakdown of the PNP ESD triggering device 118 occurring between an n-doped barrier region 220 and the p-doped well 204 of the p-doped collector 124. The breakdown of the PNP ESD triggering device 118 instead occurs between the p+ region 208 of the p-doped collector 124 and the n+ region 210 of the p-doped emitter 122.

The portions 222 of the substrate 202 may be undoped portions or p-doped, or portions of the substrate 202 that have a very low n-type dopant concentration relative to the n-doped barrier regions 220. The portions 222 may become doped with n-type dopants as a byproduct of semiconductor processing of the ESD triggering circuit 106 in that n-type dopants may migrate into the portions 222 from the n-doped barrier regions 220 (and/or other n-doped regions) during thermal operations or other types of operations that cause dopant migration. Even with the inadvertent n-type dopant migration into the portions 222 of the substrate 202, the omission of the n-doped barrier regions 220 under the p-doped collector 124 of the PNP ESD triggering device 118 results in an overall lower effective dopant concentration in the portions 222. For example, the n-type dopant concentration in the portions 222 of the substrate 202 may be included in a range of approximately 1×10¹³ n-type ions per cubic centimeter to approximately 1×10¹⁵ n-type ions per cubic centimeter, whereas the n-type dopant concentration in the n-doped barrier regions 220 may be included in a range of approximately 1×10¹⁷ n-type ions per cubic centimeter to approximately 1×10²¹ n-type ions per cubic centimeter. However, other values for these ranges are within the scope of the present disclosure.

As further shown in FIG. 2A, the ESD triggering circuit 106 may include portions 224 of the substrate 202 between the n-doped base 120 and the p-doped collector 124, and between the p-doped collector 124 and the p-doped emitter 122. The portions 224 of the substrate 202 may be located under the RPO structures 218, under the first and second STI regions 216a and 216b, and on lateral sides of the second STI regions 216b of the ESD triggering circuit 106. The portions 224 provide gaps or spacing between the n-doped well 206 of the n-doped base 120 and the p-doped well 204 of the p-doped collector 124, and between the p-doped well 204 of the p-doped collector 124 and the n-doped well 206 of the p-doped emitter 122. The portions 224 increase the distance or spacing between the p+ region 208 of the p-doped collector 124 and the n+ region 210 of the p-doped emitter 122 (e.g., relative to the p-doped well 204 and the n-doped well 206 being contiguous), and the increased distance or spacing may increase the breakdown voltage of the PNP ESD triggering device 118. Moreover, the size or width of the portions 224 may be tuned during manufacturing of the ESD triggering circuit 106 to achieve a threshold breakdown voltage for the ESD triggering circuit 106.

The portions 224 of the substrate 202 may be undoped portions or p-doped, or portions of the substrate 202 that have a very low n-type dopant concentration relative to the p-doped wells 204 and the n-doped wells 206. The portions 224 may become doped with n-type dopants and/or p-type dopants as a byproduct of semiconductor processing of the ESD triggering circuit 106 in that n-type dopants may migrate into the portions 224 from adjacent n-doped wells 206 (and/or other n-doped regions), and/or p-type dopants may migrate into the portions 224 from adjacent p-doped wells 204 (and/or other p-doped regions), during thermal operations or other types of operations that cause dopant migration. The n-type dopant concentration in the portions 224 of the substrate 202 may be included in a range of approximately 1×10¹³ n-type ions per cubic centimeter to approximately 1×10¹⁵ n-type ions per cubic centimeter, and/or the p-type dopant concentration in the portions 224 of the substrate 202 may be included in a range of approximately 1×10¹³ p-type ions per cubic centimeter to approximately 1×10¹⁵ p-type ions per cubic centimeter. However, other values for these ranges are within the scope of the present disclosure.

As further shown in FIG. 2A, the ESD triggering circuit 106 may further include terminals 226. The terminals 226 may enable a voltage to be applied to the substrate 202 to electrically bias the substrate 202. A terminal 226 may include a p-doped well 204, a p+ region 208 in the p-doped well 204, and a p+ region 212 in the p+ region 208. First STI regions 216a may be included on opposing sides of a terminal 226. In some implementations, portions 224 of the substrate 202 may be included between a terminal 226 and an adjacent n-doped base 120 of a PNP ESD triggering device 118. In some implementations, the n-doped barrier regions 220 may be omitted from under the p-doped well 204 of a terminal 226. The region 228 identifies an inner portion of the substrate 202 including a plurality of junctions between p-doped emitters 122 and p-doped collectors 124 from which charge carriers (e.g., holes) can migrate to the p-doped collectors 124.

FIG. 2B illustrates a plurality of example dimensions of the example implementation 200 of the ESD triggering circuit 106. In some implementations, one or more other example implementations of ESD triggering circuits 106 described herein may include one or more of the dimensions illustrated and described in connection with FIG. 2B.

As shown in FIG. 2B, an example dimension D1 may include a distance (e.g., width) in the x-direction between a first edge of a second STI region 216b and a second edge of the second STI region 216b. In some implementations, the example dimension D1 may be included in a range of approximately 2 micrometers to approximately 7 micrometers. If the example dimension D1 is less than approximately 2 micrometers, the breakdown voltage of the PNP ESD triggering device 118 may be too low to enable high voltage operation of the associated device circuit 102 (e.g., less than the operating voltage of the associated device circuit 102). If the example dimension D1 is greater than approximately 7 micrometers, the second STI regions 216b will not be spaced apart from doped regions (e.g., p-doped well 204, p+ region 208, and/or p+ region 212) of an adjacent p-doped collector 124, and may obstruct movement of charge carriers (e.g., holes) to the p-doped collectors 124 from areas between the p-doped collectors 124 and p-doped emitters 122. The blocking of charge carrier movement may cause high on resistance (Rₒₙ) for an ESD triggering circuit 106, which may lead to reduced operating efficiency for the ESD triggering circuit 106, or failure of ESD devices and functional devices during ESD events. In addition, if the example dimension D1 is greater than approximately 7 micrometers, the lateral size of the ESD triggering circuit 106 may increase, thereby reducing device density in the semiconductor device. However, other values for the range are within the scope of the present disclosure.

Another example dimension D2 may include a spacing or distance in the x-direction between an outer edge of an n-doped well 206 and an outer edge of an n+ region 210 included in the n-doped well 206. The n-doped well 206 and the n+ region 210 may be included in an n-doped base 120 or in a p-doped emitter 122 of a PNP ESD triggering device 118 of the ESD triggering circuit 106. In some implementations, the example dimension D2 may be included in a range of approximately 0.2 micrometers to approximately 5 micrometers. If the example dimension D2 is less than approximately 0.2 micrometers, the breakdown voltage of the PNP ESD triggering device 118 may be too high to trigger activation of the associated ESD protection circuit 104, thereby resulting in an increased likelihood of damage to the device circuit 102. If the example dimension D2 is greater than approximately 5 micrometers, the lateral size of the ESD triggering circuit 106 may increase, thereby reducing device density in the semiconductor device. However, other values for the range are within the scope of the present disclosure.

Another example dimension D3 may include a spacing or distance between an outer edge of a p-doped well 204 and an outer edge of a p+ region 208 included in the p-doped well 204. The p-doped well 204 and the p+ region 208 may be included in a terminal 226 or in a p-doped collector 124 of a PNP ESD triggering device 118 of the ESD triggering circuit 106. In some implementations, the example dimension D3 may be included in a range of approximately 0.2 micrometers to approximately 5 micrometers. If the example dimension D3 is less than approximately 0.2 micrometers, the breakdown voltage of the PNP ESD triggering device 118 may be too high to trigger activation of the associated ESD protection circuit 104, thereby resulting in an increased likelihood of damage to the device circuit 102. If the example dimension D3 is greater than approximately 5 micrometers, the lateral size of the ESD triggering circuit 106 may increase, thereby reducing device density in the semiconductor device. However, other values for the range are within the scope of the present disclosure.

Another example dimension D4 may include a width of an RPO structure 218 included in a PNP ESD triggering device 118 of the ESD triggering circuit 106. In some implementations, the example dimension D4 may be included in a range of approximately 0.5 micrometers to approximately 3 micrometers. If the example dimension D4 is less than approximately 0.5 micrometers, the breakdown voltage of the ESD triggering circuit 106 may be too low to enable high voltage operation of the associated device circuit 102 (e.g., less than the operating voltage of the associated device circuit 102). If the example dimension D4 is greater than approximately 3 micrometers, the on resistance (Rₒₙ) of the ESD triggering circuit 106 may be relatively high and lead to reduced operating efficiency for the ESD triggering circuit 106. In some implementations, a width of the RPO structure 218 within the given range may enable the RPO structure 218 to partially overlap a p-doped well 204 and a p+ region 208 of a p-doped collector 124, and partially overlap a second STI region 216b to allow the breakdown voltage and on resistance (Rₒₙ) to be within desired ranges. However, other values for the range are within the scope of the present disclosure.

Another example dimension D5 may include a dimension of a portion of a width in the x-direction of a second STI region 216b that is overlapped by an RPO structure 218. In some implementations, the example dimension D5 may be included in a range of approximately 1 micrometer to approximately 6 micrometers. If the example dimension D5 is less than approximately 1 micrometer, silicide layers may be formed on portions of the p-doped wells 204 and p+ regions 208 of the p-doped collectors 124. As a result, the breakdown voltage of the ESD triggering circuit 106 may be too low to enable high voltage operation of the associated device circuit 102 (e.g., less than the operating voltage of the associated device circuit 102). If the example dimension D5 is greater than approximately 6 micrometers, the RPO structure 218 may overlap a p+ region 212 of a p-doped emitter, which may reduce the ability of the p+ region 212 to make an ohmic contact.

Another example dimension D6 may include a spacing or distance between a p-doped well 204 of a p-doped collector 124 and an n-doped well 206 of a p-doped emitter 122 of a PNP ESD triggering device 118 of the ESD triggering circuit 106. The example dimension D6 may correspond to a width of a portion 224 of the substrate 202 between the p-doped well 204 and the n-doped well 206. In some implementations, the example dimension D6 may be included in a range of approximately 0.5 micrometers to approximately 5 micrometers. If the example dimension D6 is less than approximately 0.5 micrometers, the breakdown voltage of the PNP ESD triggering device 118 may be too low to enable high voltage operation of the associated device circuit 102 (e.g., less than the operating voltage of the associated device circuit 102). If the example dimension D6 is greater than approximately 5 micrometers, the breakdown voltage of the PNP ESD triggering device 118 may be too high to trigger activation of the associated ESD protection circuit 104, thereby resulting in an increased likelihood of damage to the device circuit 102. However, other values for the range are within the scope of the present disclosure.

Another example dimension D7 may include a spacing or distance between an outer edge of an n+ region 210 and an outer edge of an n+ region 214 included in the n+ region 210. The n+ region 210 and the n+ region 214 may be included in an n-doped base 120 of a PNP ESD triggering device 118 of the ESD triggering circuit 106. In some implementations, the example dimension D5 may be included in a range of approximately 0.2 micrometers to approximately 5 micrometers. If the example dimension D5 is less than approximately 0.2 micrometers, the breakdown voltage of the PNP ESD triggering device 118 may be too high to trigger activation of the associated ESD protection circuit 104, thereby resulting in an increased likelihood of damage to the device circuit 102. If the example dimension D5 is greater than approximately 5 micrometers, the lateral size of the ESD triggering circuit 106 may increase, thereby reducing device density in the semiconductor device. However, other values for the range are within the scope of the present disclosure.

Another example dimension D8 may include a spacing or distance between a p-doped well 204 of a p-doped collector 124 and an n-doped well 206 of an n-doped base 120 of a PNP ESD triggering device 118 of the ESD triggering circuit 106. The example dimension D8 may correspond to a width of a portion 224 of the substrate 202 between the p-doped well 204 and the n-doped well 206. In some implementations, the example dimension D8 may be included in a range of approximately 0.5 micrometers to approximately 5 micrometers. If the example dimension D8 is less than approximately 0.5 micrometers, the breakdown of the PNP ESD triggering device 118 occur between the n-doped base 120 and the p-doped collector 124 instead of between the p-doped collector 124 and a p-doped emitter 122 of the PNP ESD triggering device 118, thereby resulting in improper operation of the PNP ESD triggering device 118. If the example dimension D8 is greater than approximately 5 micrometers, the lateral size of the ESD triggering circuit 106 may increase, thereby reducing device density in the semiconductor device. However, other values for the range are within the scope of the present disclosure.

Another example dimension D9 may include a spacing or distance between a p-doped well 204 of a terminal 226 and an n-doped well 206 of an n-doped base 120 of a PNP ESD triggering device 118 of the ESD triggering circuit 106. The example dimension D3 may correspond to a width of a portion 224 of the substrate 202 between the p-doped well 204 and the n-doped well 206. In some implementations, the example dimension D9 may be included in a range of approximately 0.5 micrometers to approximately 5 micrometers. If the example dimension D9 is less than approximately 0.5 micrometers, the breakdown of the PNP ESD triggering device 118 occur between the terminal 226 and the n-doped base 120 instead of between a p-doped collector 124 and a p-doped emitter 122 of the PNP ESD triggering device 118, thereby resulting in improper operation of the PNP ESD triggering device 118. If the example dimension D8 is greater than approximately 5 micrometers, the lateral size of the ESD triggering circuit 106 may increase, thereby reducing device density in the semiconductor device. However, other values for the range are within the scope of the present disclosure.

Another example dimension D10, includes a thickness of an n-doped barrier region 220 in the ESD triggering circuit 106. In some implementations, the example dimension D10 may be included in a range of approximately 1 micrometer to approximately 10 micrometers. If the example dimension D10 is less than approximately 1 micrometer, the n-doped barrier region 220 may not provide sufficient blocking of charge carrier migration into the substrate 202, resulting in reduced electrical isolation and reduced operating efficiency in the ESD triggering circuit 106. If the example dimension D10 is greater than approximately 10 micrometers, the breakdown voltage of the ESD triggering circuit 106 may be too low to enable high voltage operation of the associated device circuit 102 (e.g., less than the operating voltage of the associated device circuit 102). However, other values for the range are within the scope of the present disclosure.

Another example dimension D11, includes a width of an n-doped barrier region 220 in the ESD triggering circuit 106. In some implementations, the example dimension D11 may be included in a range of approximately 1 micrometer to approximately 10 micrometers. If the example dimension D11 is less than approximately 1 micrometer, the n-doped barrier region 220 may not provide sufficient blocking of charge carrier migration into the substrate 202, resulting in reduced electrical isolation and reduced operating efficiency in the ESD triggering circuit 106. If the example dimension D11 is greater than approximately 10 micrometers, the breakdown voltage of the ESD triggering circuit 106 may be too low to enable high voltage operation of the associated device circuit 102 (e.g., less than the operating voltage of the associated device circuit 102). However, other values for the range are within the scope of the present disclosure.

Another example dimension D12, includes a spacing or distance between n-doped barrier regions 220 in the ESD triggering circuit 106. The example dimension D12 may correspond to a width of a portion 222 of the substrate 202 between the n-doped barrier regions 220. In some implementations, the example dimension D12 may be included in a range of approximately 1 micrometer to approximately 10 micrometers. If the example dimension D12 is less than approximately 1 micrometer, the breakdown voltage of the ESD triggering circuit 106 may be too low to enable high voltage operation of the associated device circuit 102 (e.g., less than the operating voltage of the associated device circuit 102) because breakdown of a PNP ESD triggering device 118 may occur between a p-doped well 204 of the PNP ESD triggering device 118 and an n-doped barrier region 220. If the example dimension D12 is greater than approximately 10 micrometers, the n-doped barrier regions 220 may not provide sufficient blocking of charge carrier migration into the substrate 202, resulting in reduced electrical isolation and reduced operating efficiency in the ESD triggering circuit 106. However, other values for the range are within the scope of the present disclosure.

Another example dimension D13, may include a thickness in the z-direction of a first or second STI region 216a or 216b included in the ESD triggering circuit 106. In some implementations, the example dimension D13 may be included in a range of approximately 0.1 micrometers to approximately 50 micrometers. If the example dimension D13 is less than approximately 0.1 micrometers, the first or second STI regions 216a or 216b may not provide sufficient electric field suppression in the ESD triggering circuit 106, resulting in reduced electrical isolation in the ESD triggering circuit 106. If the example dimension D13 is greater than approximately 50 micrometers, the on resistance (Rₒₙ) of the ESD triggering circuit 106 may be relatively high and lead to reduced operating efficiency for the ESD triggering circuit 106. However, other values for the range are within the scope of the present disclosure.

As indicated above, FIGS. 2A and 2B are provided as examples. Other examples may differ from what is described with regard to FIGS. 2A and 2B.

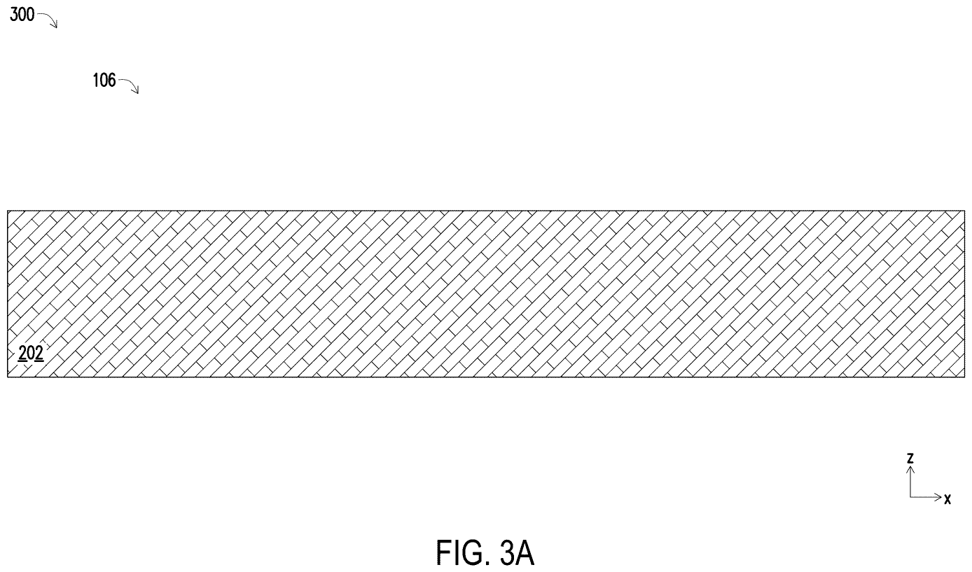

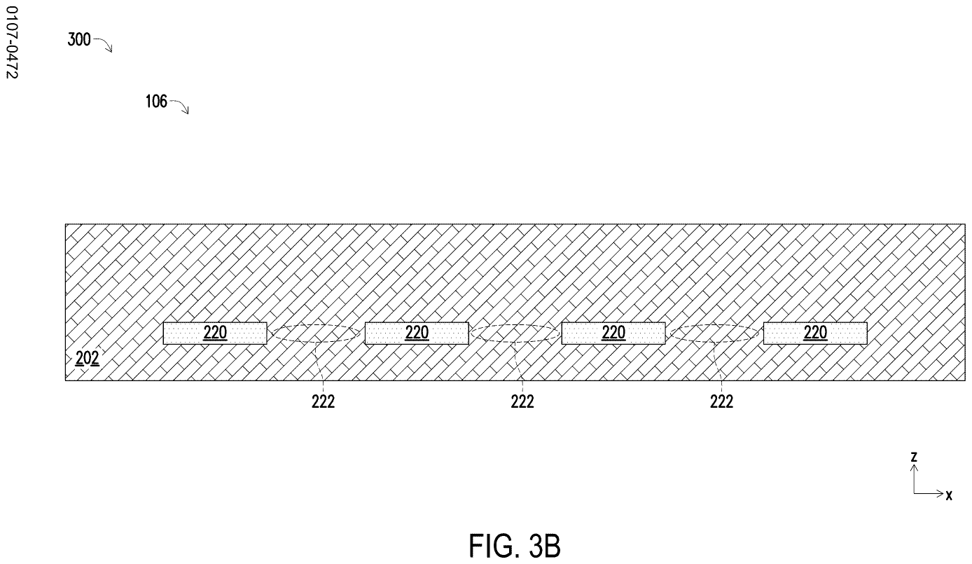

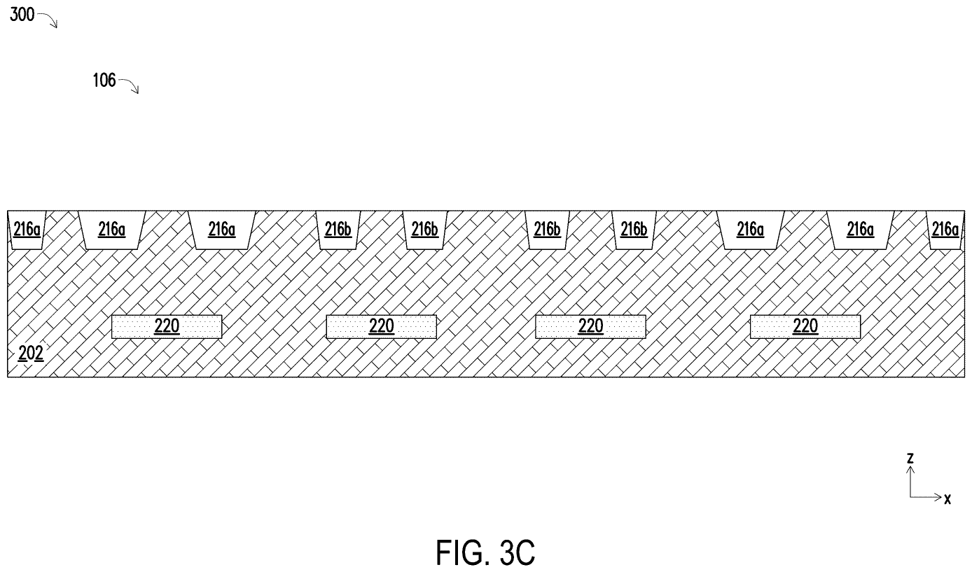

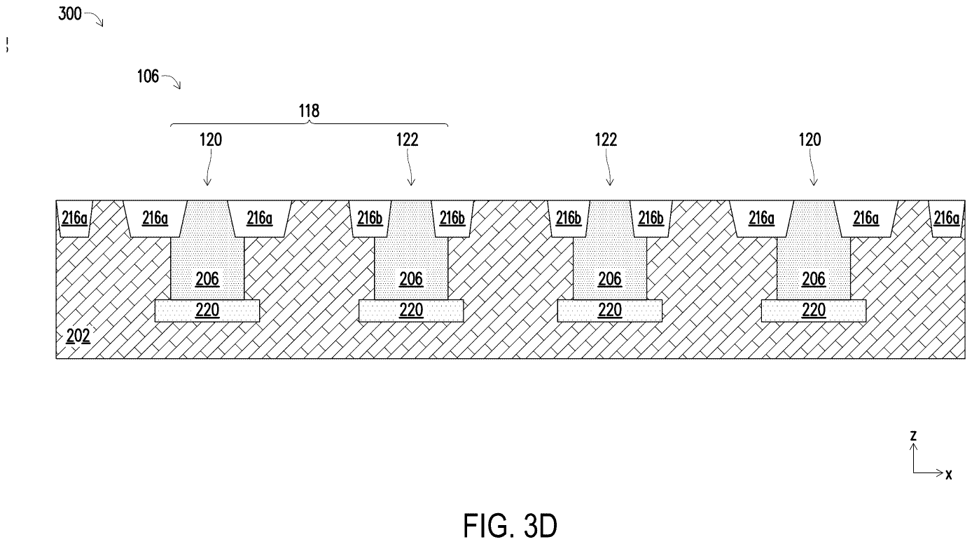

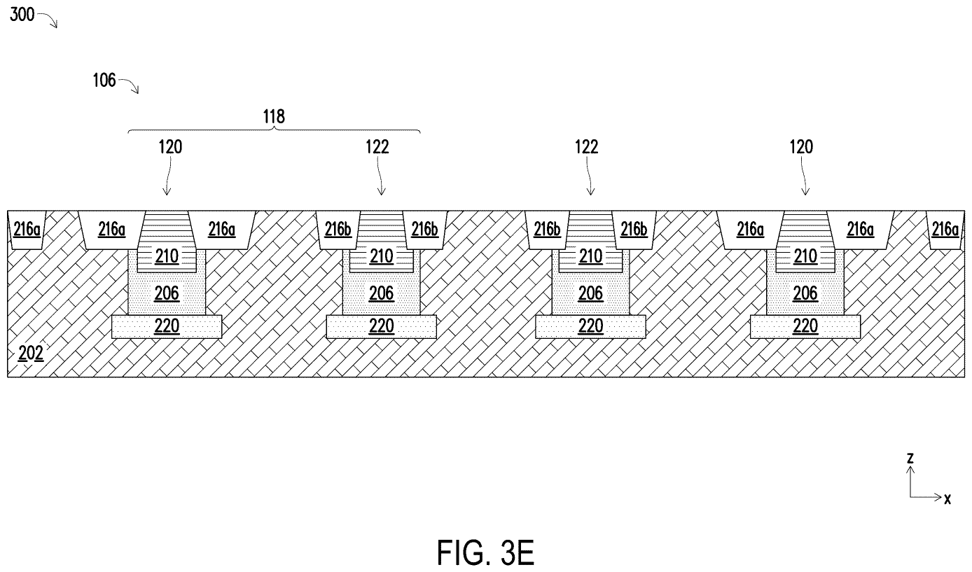

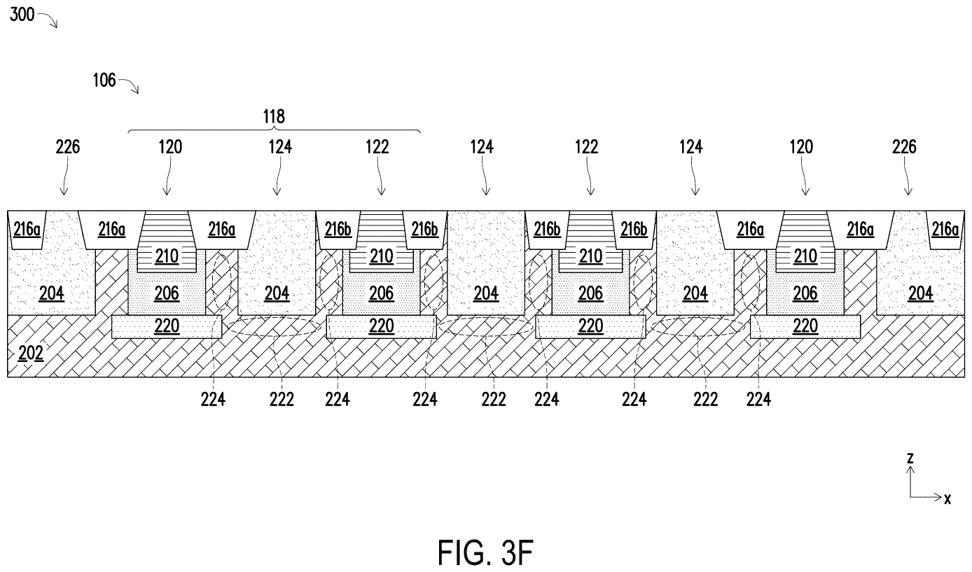

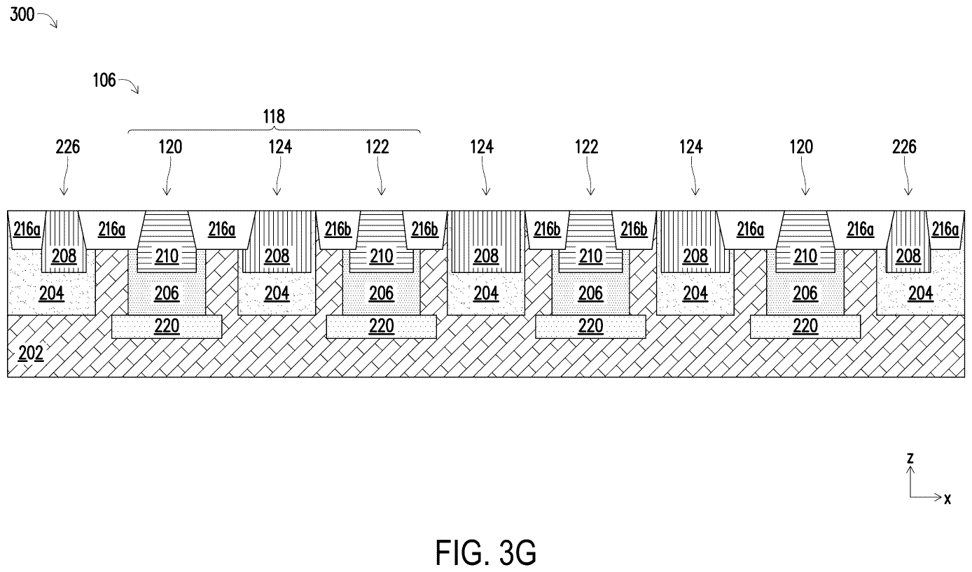

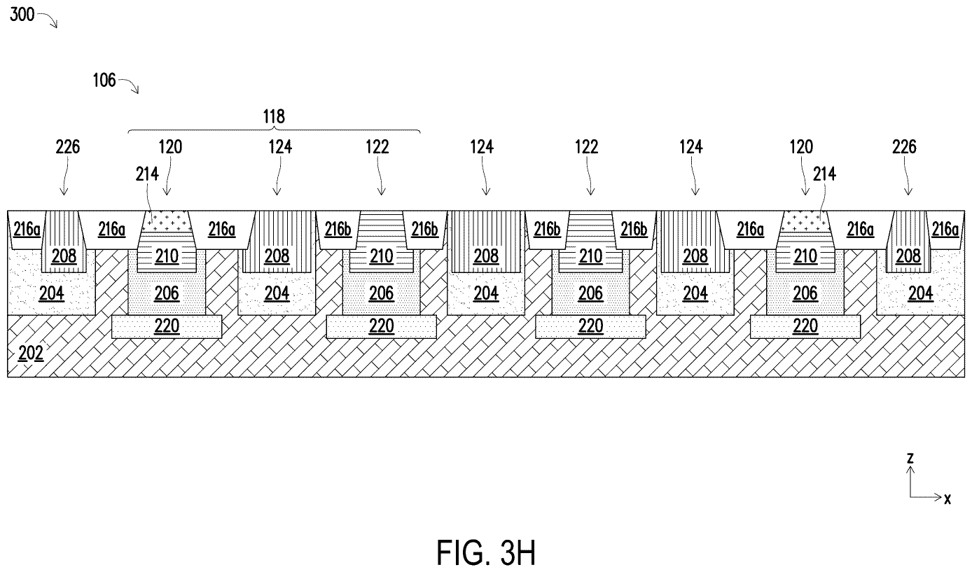

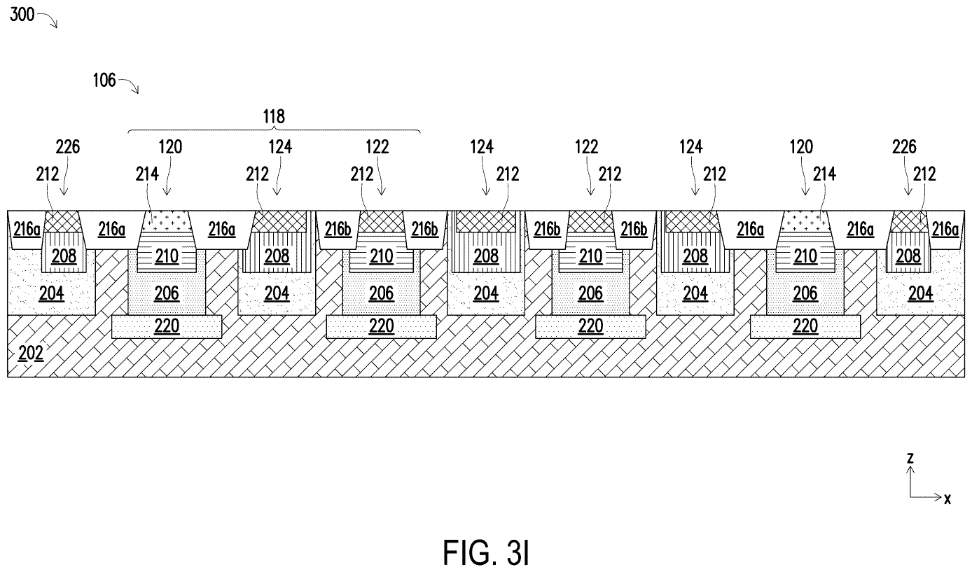

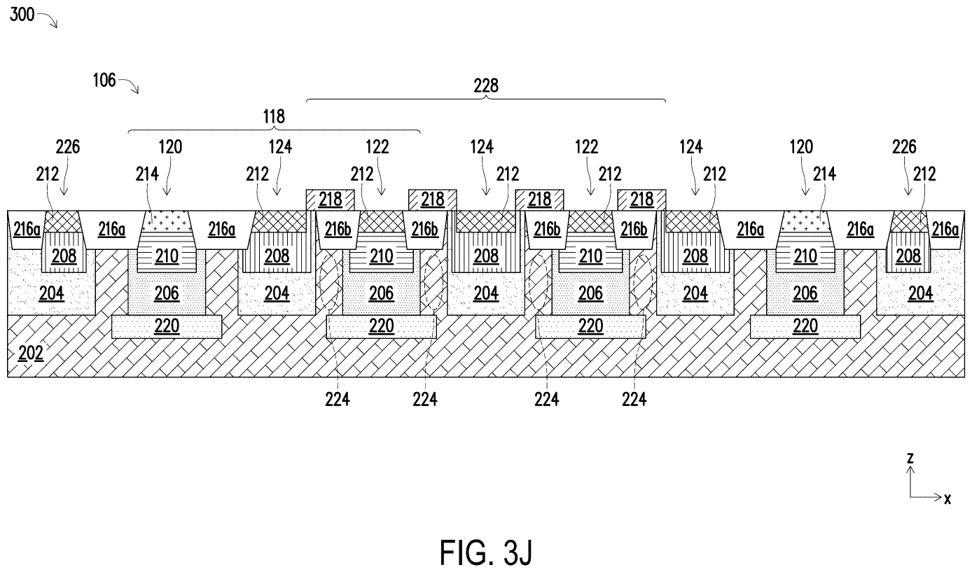

FIGS. 3A-3J are diagrams of an example implementation 300 of forming an ESD triggering circuit 106 in a semiconductor device described herein. While the example implementation 300 includes an example of forming the example implementation 200 of the ESD triggering circuit 106 illustrated and described in connection with FIGS. 2A and 2B, the semiconductor processing operations and/or techniques illustrated and described in connection with FIGS. 3A-3J (or a subset thereof) may be used to manufacture other example implementations of ESD triggering circuits 106 illustrated and described herein. In some implementations, one or more of the semiconductor processing operations described in connection with FIGS. 3A-3J are performed by one or more semiconductor processing tools and/or a wafer/die transport tool.

Turning to FIG. 3A, a substrate 202 may be provided. The substrate 202 may be provided as a semiconductor wafer, a semiconductor die, and/or another type of semiconductor substrate. In some implementations, the substrate 202 may be a doped substrate, such as a semiconductor substrate that is doped with one or more p-type dopants, a semiconductor substrate that is doped with one or more n-type dopants, and/or another type of doped substrate. In some implementations, the substrate 202 has a bulk resistivity (or volumetric resistivity) that is included in a range of approximately 1 ohm-centimeter to approximately 100 ohm-centimeters. However, other values for the range are within the scope of the present disclosure.

As shown in FIG. 3B, one or more barrier layer implantation operations may be performed to form n-doped barrier regions 220 in the substrate 202. The n-doped barrier regions 220 may be formed below the surface of the substrate 202. Moreover, the n-doped barrier regions 220 may be formed such that the n-doped barrier regions 220 are spaced apart from one another by portions 222 of the substrate 202.

In some implementations, an ion implantation tool performs the one or more well implantation operations to form the n-doped barrier regions 220 in the substrate 202 by performing an ion implantation operation to implant ions (e.g., n-type ions) into the substrate 202 to form the n-doped barrier regions 220. The ion implantation tool may direct an ion beam toward the substrate 202 such that the ions are implanted below the surface of the substrate 202 to dope the substrate 202. An implantation mask may be formed on the substrate 202, and a pattern formed in the implantation mask may be used to form the n-doped barrier regions 220 such that the n-doped barrier regions 220 are spaced apart from one another by portions 222 of the substrate 202. In some implementations, the n-doped barrier regions 220 may be formed such that the concentration of (e.g., n-type dopants) in the n-doped barrier regions 220 may be included in a range of approximately 1×10¹⁷ n-type ions per cubic centimeter to approximately 1×10²¹ n-type ions per cubic centimeter. However, other values for the range are within the scope of the present disclosure.

As shown in FIG. 3C, an STI formation operation is performed to form first and second STI regions 216a and 216b in the substrate 202. The first and second STI regions 216a and 216b may be formed above the n-doped barrier regions 220. In some implementations, one or more other semiconductor processing operations are performed after the one or more well implantation operations and prior to the STI formation operation, such as an epitaxial operation to form one or more source/drain regions of the transistors 114 in a device circuit 102 of the semiconductor device. To form the first and second STI regions 216a and 216b, recesses may be formed in the substrate 202, and the material of the first and second STI regions 216a and 216b may be deposited in the recesses.

In some implementations, a pattern in a photoresist layer is used to etch the substrate 202 to form the recesses. In these implementations, a deposition tool may form the photoresist layer on the substrate 202. An exposure tool may expose the photoresist layer to a radiation source to pattern the photoresist layer. A developer tool may develop and remove portions of the photoresist layer to expose the pattern. An etch tool may etch the substrate 202 based on the pattern to form the recesses in the substrate 202. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the substrate 202 based on a pattern.

A deposition tool may deposit the material of the first and second STI regions 216a and 216b in a physical vapor deposition (PVD) operation, an atomic layer deposition (ALD) operation, a chemical vapor deposition (CVD) operation, an epitaxy operation, an oxidation operation, and/or another suitable deposition operation. In some implementations, a planarization tool may planarize the first and second STI regions 216a and 216b after the deposition tool deposits the first and second STI regions 216a and 216b.

As shown in FIG. 3D, one or more well implantation operations may be performed to form n-doped wells 206 in the substrate 202. The n-doped wells 206 may be formed below the surface of the substrate 202. Moreover, the n-doped wells 206 may be formed above and/or over the n-doped barrier regions 220. Forming the n-doped wells 206 may be a part of a process of forming an n-doped base 120 of a PNP ESD triggering device 118 included in the ESD triggering circuit 106, and/or may be a part of a process of forming a p-doped emitter 122 of the PNP ESD triggering device 118.

In some implementations, an ion implantation tool performs the one or more well implantation operations to form the n-doped wells 206 in the substrate 202 by performing an ion implantation operation to implant ions (e.g., n-type ions) into the substrate 202 to form the n-doped wells 206. The ion implantation tool may direct an ion beam toward the substrate 202 such that the ions are implanted below the surface of the substrate 202 to dope the substrate 202. An implantation mask may be formed on the substrate 202, and a pattern formed in the implantation mask may be used to form the n-doped wells 206 above and/or over the n-doped barrier regions 220.

As shown in FIG. 3E, one or more n+ implantation operations may be performed to form n+ regions 210 in the substrate 202. The n+ regions 210 may be formed in the n-doped wells 206. In this way each n+ region 210 is included within an associated n-doped well 206. Forming the n+ regions 210 may be a part of the process of forming the n-doped base 120 of the PNP ESD triggering device 118 included in the ESD triggering circuit 106, and/or may be a part of the process of forming the p-doped emitter 122 of the PNP ESD triggering device 118.

In some implementations, an ion implantation tool performs the one or more well implantation operations to form the n+ regions 210 in the substrate 202 by performing an ion implantation operation to implant ions (e.g., n-type ions) into the substrate 202 to form the n+ regions 210. The ion implantation tool may direct an ion beam toward the substrate 202 such that the ions are implanted below the surface of the substrate 202 to dope the substrate 202. An implantation mask may be formed on the substrate 202, and a pattern formed in the implantation mask may be used to form the n+ regions 210 in the n-doped wells 206.

As shown in FIG. 3F, one or more well implantation operations may be performed to form p-doped wells 204 in the substrate 202. Forming the p-doped wells 204 may be a part of a process of forming one or more terminals 226 of the ESD protection circuit, and/or a part of a process forming an p-doped collector 124 of the PNP ESD triggering device 118 included in the ESD triggering circuit 106.

The p-doped wells 204 may be formed below the surface of the substrate 202 and adjacent to one or more n-doped wells 206. The p-doped wells 204 may be formed above and/or over the portions 222 of the substrate 202 between the n-doped barrier regions 220. Moreover, the p-doped wells 204 may be formed such that the p-doped wells 204 are separated or spaced apart from adjacent n-doped wells 206 by portions 224 of the substrate 202.

In some implementations, the ion implantation tool performs the one or more well implantation operations to form the p-doped wells 204 in the substrate 202 by performing an ion implantation operation to implant ions (e.g., p-type ions) into the substrate 202 to form the p-doped wells 204. The ion implantation tool may direct an ion beam toward the substrate 202 such that the ions are implanted below the surface of the substrate 202 to dope the substrate 202. An implantation mask may be formed on the substrate 202, and a pattern formed in the implantation mask may be used to form the p-doped wells 204 above and/or over the portions 222 in the substrate. Moreover, the pattern formed in the implantation mask may be used to form the p-doped wells 204 between adjacent n-doped wells 206 such that the portions 224 of the substrate 202 separate or isolate the p-doped wells 204 and the adjacent n-doped wells 206.

As shown in FIG. 3G, one or more p+ implantation operations may be performed to form p+ regions 208 in the substrate 202. The p+ regions 208 may be formed in the p-doped wells 204. In this way, each p+ region 208 is included within an associated p-doped well 204.

In some implementations, the ion implantation tool performs the one or more well implantation operations to form the p+ regions 208 in the substrate 202 by performing an ion implantation operation to implant ions (e.g., p-type ions) into the substrate 202 to form the p+ regions 208. The ion implantation tool may direct an ion beam toward the substrate 202 such that the ions are implanted below the surface of the substrate 202 to dope the substrate 202. An implantation mask may be formed on the substrate 202, and a pattern formed in the implantation mask may be used to form the p+ regions 208 in the p-doped wells 204.

In some implementations, the operations illustrated and described in connection with FIGS. 3D3G may be performed in another order. For example, the n-doped wells 206 may be formed, followed by the p-doped wells 204, followed by the n+ regions 212, followed by the p+ regions 208. As another example, the n-doped wells 206 may be formed, followed by the p-doped wells 204, followed by the p+ regions 208, followed by the n+ regions 210. As another example, the p-doped wells 204 may be formed, followed by the n-doped wells 206, followed by the p+ regions 208, followed by the n+ regions 210. As another example, the p-doped wells 204 may be formed, followed by the n-doped wells 206, followed by the n+ regions 210, followed by the p+ regions 208.

As shown in FIG. 3H, one or more n+ implantation operations may be performed to form n+ regions 214 in the substrate 202. An n+ region 214 may be formed in the n+ region 210 of the n-doped base 120 as a part of the process to form the PNP ESD triggering device 118 included in the ESD triggering circuit 106.

In some implementations, the ion implantation tool performs the one or more well implantation operations to form the n+ regions 214 in the substrate 202 by performing an ion implantation operation to implant ions (e.g., n-type ions) into the substrate 202 to form the n+ regions 214. The ion implantation tool may direct an ion beam toward the substrate 202 such that the ions are implanted below the surface of the substrate 202 to dope the substrate 202. An implantation mask may be formed on the substrate 202, and a pattern formed in the implantation mask may be used to form the n+ region 214 in the n+ region 210 of the n-doped base 120.

As shown in FIG. 3I, one or more p+ implantation operations may be performed to form p+ regions 212 in the substrate 202. A p+ region 212 may be formed in the n+ region 210 of the p-doped emitter 122 as a part of the process to form the PNP ESD triggering device 118 included in the ESD triggering circuit 106. Another p+ region 212 may be formed in the p+ region 208 of the p-doped collector 124 as a part of the process to form the PNP ESD triggering device 118 included in the ESD triggering circuit 106. Another p+ region 212 may be formed in the p+ region 208 of a terminal 226 of the ESD triggering circuit 106.

In some implementations, the ion implantation tool performs the one or more well implantation operations to form the p+ regions 212 in the substrate 202 by performing an ion implantation operation to implant ions (e.g., p-type ions) into the substrate 202 to form the p+ regions 212. The ion implantation tool may direct an ion beam toward the substrate 202 such that the ions are implanted below the surface of the substrate 202 to dope the substrate 202. An implantation mask may be formed on the substrate 202, and a pattern formed in the implantation mask may be used to form the p+ regions 212 in the n+ region 210 of the p-doped emitter 122, in the p+ region 208 of the p-doped collector 124, and/or in the p+ region 208 of the terminal 226.

In some implementations, the operations illustrated and described in connection with FIGS. 3H and 3I may be performed in another order. For example, the p+ regions 212 may be formed, and the n+ regions 214 may be formed after the p+ regions 212 are formed. Additionally and/or alternatively, one or more other semiconductor processing operations are performed after the operations illustrated and described in connection with FIGS. 3D-3G and prior to the operations illustrated and described in connection with FIGS. 3H and 3I, such as a gate poly operation to form one or more gate structures of the transistors 114 in a device circuit 102 of the semiconductor device.

As shown in FIG. 3J, an RPO formation operation may performed to form RPO structures 218 over and/or on the surface of the substrate 202. A deposition tool may deposit the material of the RPO structures 218 in a PVD operation, an ALD operation, a CVD operation, an epitaxy operation, an oxidation operation, and/or another suitable deposition operation. In some implementations, a planarization tool planarizes the RPO structures 218 after a deposition tool deposits the RPO structures 218. In some implementations, the material of the RPO structures 218 is deposited as a blanket layer, and an etch tool performs an etch back operation to remove portions of the blanket layer, where remaining portions of the blanket layer correspond to the RPO structures 218.

The RPO structures 218 may be formed such that an RPO structure 218 is included over and/or on a portion 224 of the substrate 202 between the p-doped well 204 of the p-doped collector 124 and the n-doped well 206 of the p-doped emitter 122. In some implementations, the RPO structure 218 may be formed such that the RPO structure 218 is included over and/or on a portion of the p-doped well 204, over and/or on a portion of the n-doped well 206, over and/or on a portion of the p+ region 208 of the p-doped collector 124, over and/or on a portion of the second STI region 216b, and/or over and/or on a portion of the n+ region 210 of the p-doped emitter 122, among other examples.

As indicated above, FIGS. 3A-3J are provided as an example. Other examples may differ from what is described with regard to FIGS. 3A-3J.

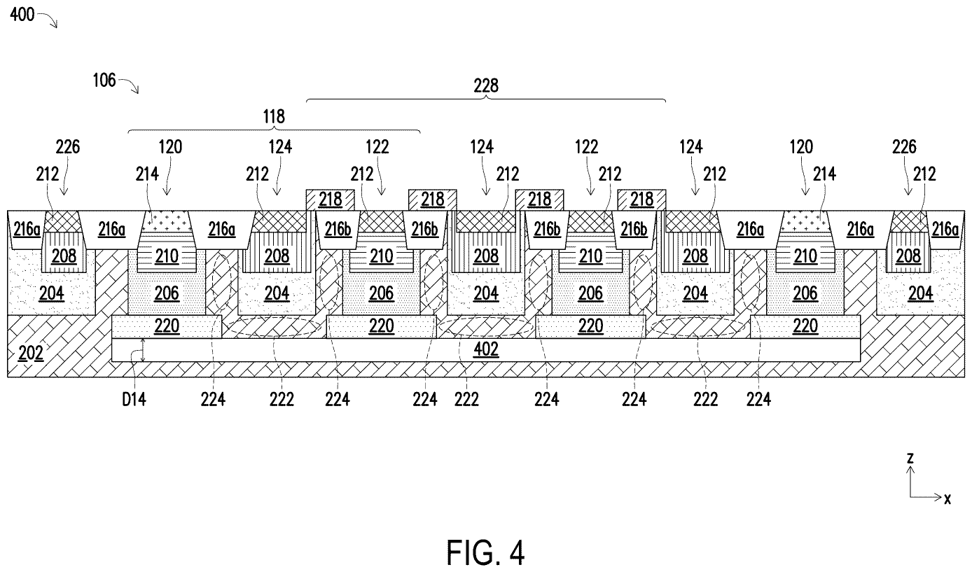

FIG. 4 is a diagram of an example implementation 400 of an ESD triggering circuit 106 described herein. The example implementation 400 of the ESD triggering circuit 106 described in connection with FIG. 4 may be included in a semiconductor device, such as the semiconductor device 100, the semiconductor device 126, the semiconductor device 128, and/or another semiconductor device that includes high voltage devices.

FIG. 4 illustrates an example implementation 400 of an ESD triggering circuit 106. As shown in FIG. 4, the example implementation 400 of the ESD triggering circuit 106 may include a similar arrangement of layers and/or structures as the example implementation 200 of the ESD triggering circuit 106 illustrated and described in connection with FIGS. 2A and 2B. For example, the example implementation 400 of the ESD triggering circuit 106 may include components 202-224. The example implementation 400 of the ESD triggering circuit 106 may further include a deep n-doped barrier layer 402. The deep n-doped barrier layer 402 may be included below and/or under the n-doped barrier regions 220, and may provide additional charge carrier migration blocking (e.g., in combination with the n-doped barrier regions 220) with minimal decrease in breakdown voltage of the PNP ESD triggering device 118 because of the distance between the deep n-doped barrier layer 402 and the p-doped wells 204 in the ESD triggering circuit 106.

The deep n-doped barrier layer 402 may include a continuous layer that extends continuously between and under a plurality of n-doped barrier regions 220. The deep n-doped barrier layer 402 may include a similar dopant concentration and dopant type as the n-doped barrier regions 220. The example implementation 400 of the ESD triggering circuit 106 may be formed by a similar set of semiconductor processing operations illustrated and described in connection with FIGS. 3A-3J. The deep n-doped barrier layer 402 may be formed before or after the one or more barrier layer implantation operations, illustrated and described in connection with FIG. 3B, to form the n-doped barrier regions 220.

Another example dimension D14, includes a thickness of the deep n-doped barrier layer 402 in the ESD triggering circuit 106. In some implementations, the example dimension D14 may be included in a range of approximately 1 micrometer to approximately 10 micrometers. If the example dimension D14 is less than approximately 1 micrometer, the deep n-doped barrier layer 402 may not provide sufficient blocking of charge carrier migration into the substrate 202, resulting in reduced electrical isolation and reduced operating efficiency in the ESD triggering circuit 106. If the example dimension D14 is greater than approximately 10 micrometers, the breakdown voltage of the ESD triggering circuit 106 may be too low to enable high voltage operation of the associated device circuit 102 (e.g., less than the operating voltage of the associated device circuit 102). However, other values for the range are within the scope of the present disclosure.

In the example implementation 400 shown in FIG. 4, the p-doped wells 204 of the p-doped collectors 124 are spaced apart from the n-doped wells 206 of the n-doped bases 120 and of the p-doped emitters 122. Portions of the substrate 202 occupy the spaces between the p-doped wells 204 and the n-doped wells 206. As an alternative to the example implementation 400, the edges of the p-doped wells 204 may be in contact with edges of the n-doped wells 206, while other elements as shown in FIG. 4 have the same arrangement as in the example implementation 400.

As indicated above, FIG. 4 is provided as an example. Other examples may differ from what is described with regard to FIG. 4.

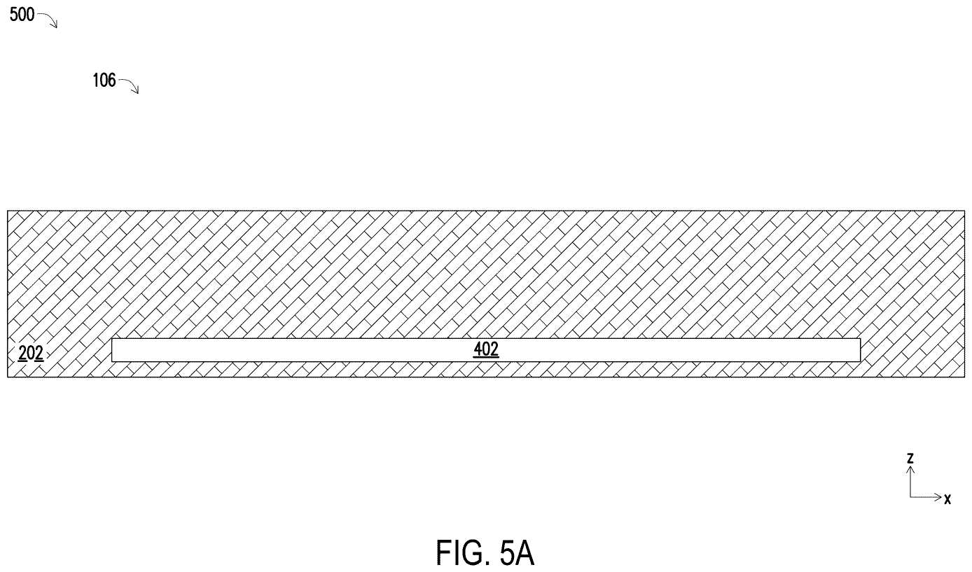

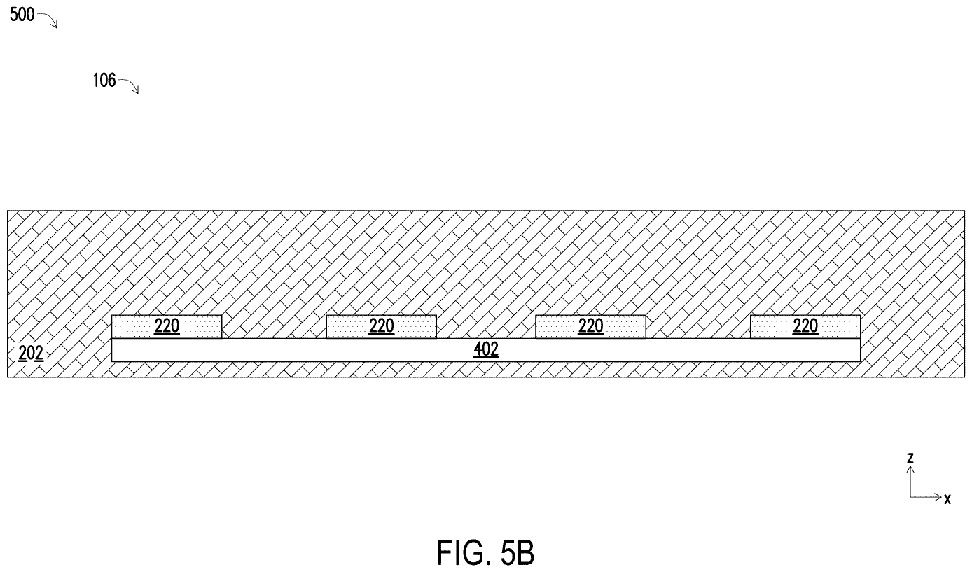

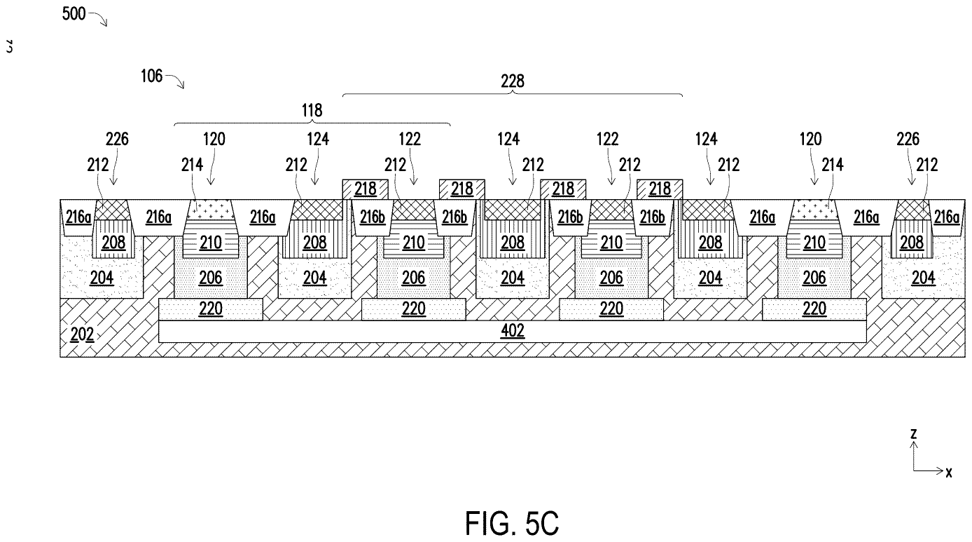

FIGS. 5A-5C are diagrams of an example implementation 500 of forming an ESD triggering circuit 106 in a semiconductor device described herein. While the example implementation 500 includes an example of forming the example implementation 400 of the

ESD triggering circuit 106 illustrated and described in connection with FIG. 4, the semiconductor processing operations and/or techniques illustrated and described in connection with FIGS. 5A-5C (or a subset thereof) may be used to manufacture other example implementations of ESD triggering circuits 106 illustrated and described herein. In some implementations, one or more of the semiconductor processing operations described in connection with FIGS. 5A-5C are performed by one or more of the semiconductor processing tools and/or a wafer/die transport tool.

Turning to FIG. 5A, a substrate 202 may be provided. The substrate 202 may be provided as a semiconductor wafer, a semiconductor die, and/or another type of semiconductor substrate. In some implementations, the substrate 202 may be a doped substrate, such as a semiconductor substrate that is doped with one or more p-type dopants, a semiconductor substrate that is doped with one or more n-type dopants, and/or another type of doped substrate. In some implementations, the substrate 202 has a bulk resistivity (or volumetric resistivity) that is included in a range of approximately 1 ohm-centimeter to approximately 100 ohm-centimeters. However, other values for the range are within the scope of the present disclosure.

As further shown in FIG. 5A, a barrier layer implantation operation may be performed to form a deep n-doped barrier layer 402 in the substrate 202. The deep n-doped barrier layer 402 may be formed below the surface of the substrate 202.

In some implementations, an ion implantation tool performs the one or more well implantation operations to form the deep n-doped barrier layer 402 in the substrate 202 by performing an ion implantation operation to implant ions (e.g., n-type ions) into the substrate 202 to form the deep n-doped barrier layer 402. The ion implantation tool may direct an ion beam toward the substrate 202 such that the ions are implanted below the surface of the substrate 202 to dope the substrate 202. In some implementations, the deep n-doped barrier layer 402 may be formed such that the concentration of (e.g., n-type dopants) in the deep n-doped barrier layer 402 may be included in a range of approximately 1×10¹⁷ n-type ions per cubic centimeter to approximately 1×10²¹ n-type ions per cubic centimeter. However, other values for the range are within the scope of the present disclosure.

As shown in FIG. 5B, one or more barrier layer implantation operations may be performed to form n-doped barrier regions 220 in the substrate 202. The n-doped barrier regions 220 may be formed below the surface of the substrate 202. The n-doped barrier regions 220 may be formed such that the n-doped barrier regions 220 are spaced apart from one another by portions 222 of the substrate 202. Moreover, the n-doped barrier regions 220 may be formed over and/or on the deep n-doped barrier layer 402.

In some implementations, an ion implantation tool performs the one or more well implantation operations to form the n-doped barrier regions 220 in the substrate 202 by performing an ion implantation operation to implant ions (e.g., n-type ions) into the substrate 202 to form the n-doped barrier regions 220. The ion implantation tool may direct an ion beam toward the substrate 202 such that the ions are implanted below the surface of the substrate 202 to dope the substrate 202. An implantation mask may be formed on the substrate 202, and a pattern formed in the implantation mask may be used to form the n-doped barrier regions 220 such that the n-doped barrier regions 220 are spaced apart from one another by portions 222 of the substrate 202. In some implementations, the n-doped barrier regions 220 may be formed such that the concentration of (e.g., n-type dopants) in the n-doped barrier regions 220 may be included in a range of approximately 1×10¹⁷ n-type ions per cubic centimeter to approximately 1×10²¹ n-type ions per cubic centimeter. However, other values for the range are within the scope of the present disclosure.

In some implementations, an ion implantation tool forms the n-doped barrier regions 220 prior to formation of the deep n-doped barrier layer 402. For example, the ion implantation tool may form the n-doped barrier regions 220, and may for the deep n-doped barrier layer 402 below and/or under the n-doped barrier regions 220 after forming the n-doped barrier regions 220.

As shown in FIG. 5C, additional semiconductor processing operations illustrated and described in connection with FIGS. 3C-3J may be performed to form the example implementation 400 of the ESD triggering circuit 106, and/or another example implementation of an ESD triggering circuit 106 described herein).

As indicated above, FIGS. 5A-5C are provided as an example. Other examples may differ from what is described with regard to FIGS. 5A-5C.

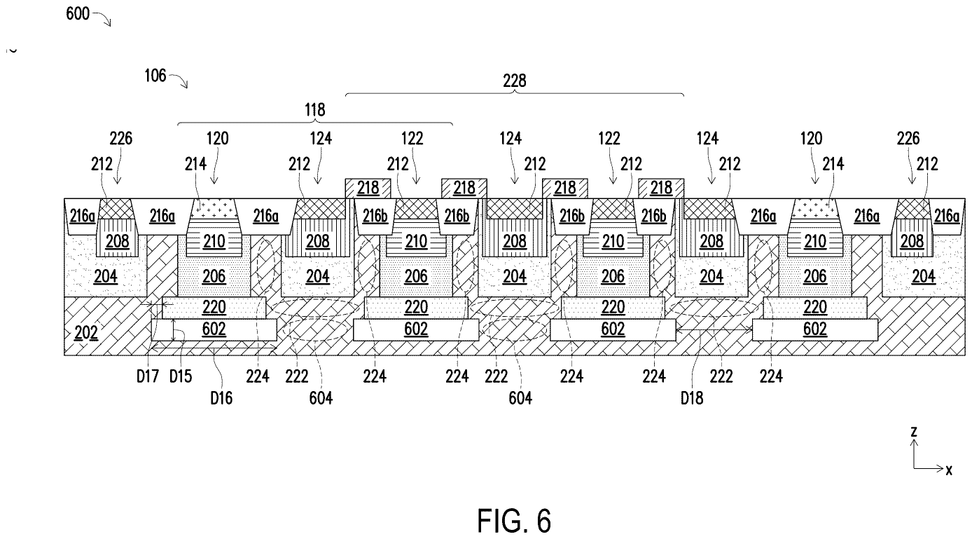

FIG. 6 illustrates an example implementation 600 of an ESD triggering circuit 106. As shown in FIG. 6, the example implementation 600 of the ESD triggering circuit 106 may include a similar arrangement of layers and/or structures as the example implementation 200 of the ESD triggering circuit 106 illustrated and described in connection with FIGS. 2A and 2B. For example, the example implementation 600 of the ESD triggering circuit 106 may include components 202-224. The example implementation 600 of the ESD triggering circuit 106 may further include a plurality of deep n-doped barrier regions 602. A deep n-doped barrier region 602 may be included below and/or under an n-doped barrier region 220, and may provide additional charge carrier migration blocking (e.g., in combination with the n-doped barrier region 220). Adjacent deep n-doped barrier regions 602 may be spaced apart or separated by portions 604 of the substrate 202 below and/or under the p-doped wells 204 of the p-doped collectors 124 of the ESD triggering circuit 106, thereby providing minimal decrease in breakdown voltage of the PNP ESD triggering devices 118 of the ESD triggering circuit 106. The portions 604 of the substrate 202 may be located below and/or under the portions 222 of the substrate 202 between adjacent n-doped barrier regions 220.

The deep n-doped barrier regions 602 may include a similar dopant concentration and dopant type as the n-doped barrier regions 220. The example implementation 600 of the ESD triggering circuit 106 may be formed by a similar set of semiconductor processing operations illustrated and described in connection with FIGS. 3A-3J and/or 5A-5C. The deep n-doped barrier regions 602 may be formed in the barrier layer formation operation, illustrated and described in connection with FIG. 5A, in place of the deep n-doped barrier layer 402. The deep-n-doped barrier regions 602 may be formed before or after the one or more barrier layer implantation operations, illustrated and described in connection with FIG. 3B and/or FIG. 5B, to form the n-doped barrier regions 220.

FIG. 6 illustrates a plurality of example dimensions of the example implementation 600 of the ESD triggering circuit 106. In some implementations, one or more other example implementations of ESD triggering circuits 106 described herein may include one or more of the dimensions illustrated and described in connection with FIG. 6.

Another example dimension D15, includes a thickness of a deep n-doped barrier region 602 in the ESD triggering circuit 106. In some implementations, the example dimension D15 may be included in a range of approximately 1 micrometer to approximately 10 micrometers. If the example dimension D15 is less than approximately 1 micrometer, the deep n-doped barrier region 602 may not provide sufficient blocking of charge carrier migration into the substrate 202, resulting in reduced electrical isolation and reduced operating efficiency in the ESD triggering circuit 106. If the example dimension D15 is greater than approximately 10 micrometers, the breakdown voltage of the ESD triggering circuit 106 may be too low to enable high voltage operation of the associated device circuit 102 (e.g., less than the operating voltage of the associated device circuit 102). However, other values for the range are within the scope of the present disclosure.

Another example dimension D16, includes a width of a deep n-doped barrier region 602 in the ESD triggering circuit 106. In some implementations, the example dimension D16 may be included in a range of approximately 1 micrometer to approximately 5 micrometers. If the example dimension D16 is less than approximately 1 micrometer, the deep n-doped barrier region 602 may not provide sufficient blocking of charge carrier migration into the substrate 202, resulting in reduced electrical isolation and reduced operating efficiency in the ESD triggering circuit 106. If the example dimension D16 is greater than approximately 5 micrometers, the breakdown voltage of the ESD triggering circuit 106 may be too low to enable high voltage operation of the associated device circuit 102 (e.g., less than the operating voltage of the associated device circuit 102). However, other values for the range are within the scope of the present disclosure.

Another example dimension D17, includes a lateral extension of a deep n-doped barrier region 602 from an outer edge of an n-doped barrier region 220 over the deep n-doped barrier region 602. In some implementations, the example dimension D17 may be included in a range of approximately −5 micrometers (meaning that the deep n-doped barrier region 602 does not laterally extend outward from the outer edge of the n-doped barrier region 220) to approximately 5 micrometers. If the example dimension D17 is less than approximately −5 micrometers, the deep n-doped barrier region 602 may not provide sufficient blocking of charge carrier migration into the substrate 202, resulting in reduced electrical isolation and reduced operating efficiency in the ESD triggering circuit 106. If the example dimension D17 is greater than approximately 5 micrometers, the breakdown voltage of the ESD triggering circuit 106 may be too low to enable high voltage operation of the associated device circuit 102 (e.g., less than the operating voltage of the associated device circuit 102). However, other values for the range are within the scope of the present disclosure.

Another example dimension D18, includes a spacing or distance between adjacent deep n-doped barrier regions 602 in the ESD triggering circuit 106. The example dimension D18 may correspond to a width of a portion 604 of the substrate 202 between the adjacent deep n-doped barrier regions 602. In some implementations, the example dimension D18 may be included in a range of approximately 0.5 micrometers to approximately 5 micrometers. If the example dimension D18 is less than approximately 0.5 micrometers, the breakdown voltage of the ESD triggering circuit 106 may be too low to enable high voltage operation of the associated device circuit 102 (e.g., less than the operating voltage of the associated device circuit 102) because breakdown of a PNP ESD triggering device 118 may occur between a p-doped well 204 of the PNP ESD triggering device 118 and a deep n-doped barrier region 602. If the example dimension D18 is greater than approximately 5 micrometers, the deep n-doped barrier regions 602 may not provide sufficient blocking of charge carrier migration into the substrate 202, resulting in reduced electrical isolation and reduced operating efficiency in the ESD triggering circuit 106. However, other values for the range are within the scope of the present disclosure.

In the example implementation 600 shown in FIG. 6, the p-doped wells 204 of the p-doped collectors 124 are spaced apart from the n-doped wells 206 of the n-doped bases 120 and of the p-doped emitters 122. Portions of the substrate 202 occupy the spaces between the p-doped wells 204 and the n-doped wells 206. As an alternative to the example implementation 600, the edges of the p-doped wells 204 may be in contact with edges of the n-doped wells 206, while other elements as shown in FIG. 6 have the same arrangement as in the example implementation 600.

As indicated above, FIG. 6 is provided as an example. Other examples may differ from what is described with regard to FIG. 6.

FIGS. 7A and 7B illustrate example implementations of an ESD triggering circuit 106. As shown in FIG. 7A, the example implementation 700 of the ESD triggering circuit 106 may include a similar arrangement of layers and/or structures as the example implementation 200 of the ESD triggering circuit 106 illustrated and described in connection with FIGS. 2A and 2B. For example, the example implementation 700 of the ESD triggering circuit 106 may include components 202-218, and 224. However, instead of the n-doped barrier regions 220 and the portions 222 of the substrate 202 between the n-doped barrier regions 220, the example implementation 700 of the ESD triggering circuit 106 may include an n-doped barrier layer 702 in place of the n-doped barrier regions 220.

The n-doped barrier layer 702 may include a continuous layer that extends continuously between and under the n-doped bases 120, the p-doped emitters 122, and the p-doped collectors 124. More specifically, the n-doped barrier layer 702 is formed under the p-doped wells 204 of the p-doped collectors 124, and under the n-doped wells 206 of the n-doped bases 120 and of the p-doped emitters 122. The n-doped barrier layer 702 may include a similar dopant concentration and dopant type as the n-doped barrier regions 220. For example, the n-doped barrier layer 702 may be a region of the substrate 202 that is doped with one or more n-type dopants, such as phosphorous (P), arsenic (As), bismuth (Bi), and/or antimony (Sb), among other examples. The n-doped barrier layer 702 may be formed in place of the n-doped barrier regions 220 as a part of the one or more barrier layer implantation operation illustrated and described in connection with FIGS. 3B and/or 3B.

In the example implementation 700 in FIG. 7A, the ESD triggering circuit 106 includes 2 “fingers” of PNP ESD triggering devices 118 including 2 n-doped bases 120, 3 p-doped collectors 124, and 2 p-doped emitters 122.

FIG. 7A illustrates an example dimension of the n-doped barrier layer 702 of the example implementation 700 of the ESD triggering circuit 106. In some implementations, one or more other example implementations of ESD triggering circuits 106 described herein may include the dimension illustrated and described in connection with FIG. 7A.

Another example dimension D19 includes a thickness of an n-doped barrier layer 702 in the ESD triggering circuit 106. In some implementations, the example dimension D19 may be included in a range of approximately 1 micrometer to approximately 10 micrometers. If the example dimension D19 is less than approximately 1 micrometer, the n-doped barrier layer 702 may not provide sufficient blocking of charge carrier migration into the substrate 202, resulting in reduced electrical isolation and reduced operating efficiency in the ESD triggering circuit 106. If the example dimension D19 is greater than approximately 10 micrometers, the breakdown voltage of the ESD triggering circuit 106 may be too low to enable high voltage operation of the associated device circuit 102 (e.g., less than the operating voltage of the associated device circuit 102). However, other values for the range are within the scope of the present disclosure.

As shown in FIG. 7B, the example implementation 704 of the ESD triggering circuit 106 may include a similar arrangement of layers and/or structures as the example implementation 700 of the ESD triggering circuit 106 illustrated and described in connection with FIG. 7A. For example, the example implementation 704 of the ESD triggering circuit 106 may include components 202-218 and 702. However, in the example implementation 704 of the ESD triggering circuit 106, edges of the p-doped wells 204 are in contact with edges of the n-doped wells 206, so that the p-doped wells 204 are not spaced apart from the n-doped wells 206. As a result, portions 224 of the substrate 202 between the p-doped wells 204 and the n-doped wells 206 are not present, and the p-doped wells 204 and the n-doped wells 206 border each other at interfaces 706.

As can be seen in FIG. 7B, the second STI regions 216b are spaced apart from edges of the p+ region 208 and the p+ region 212 of a p-doped collector 124, and are in contact with (e.g., abut) a portion of the p-doped well 204. A second STI region 216b being spaced apart from the p+ region 208 and the p+ region 212 of an adjacent p-doped collector 124 allows for unobstructed movement of holes to the p-doped collector 124 from the interface 706 between the p-doped collector 124 and an adjacent p-doped emitter 122. As a result, Rₒₙ is reduced in comparison to the Rₒₙ for high voltage ESD triggering devices with other STI region arrangements.

Two second STI regions 216b on opposite sides of a p-doped emitter 122 in the x-direction are in contact with the n-doped well 206, n+ region 210, and p+ region 212 of the p-doped emitter 122. Portions of bottom sides and left or right sides of the two second STI regions 216b abut the n-doped well 206, n+ region 210, and/or p+ region 212 of the p-doped emitter 122. Each of the two second STI regions 216b may also contact the p-doped wells 204 and be spaced apart from p+ regions 208, and p+ regions 212 of adjacent p-doped collectors 124 on opposite sides of the p-doped emitter 122 in the x-direction. Two first STI regions 216a on opposite sides of an n-doped base 120 in the x-direction are in contact with the n-doped well 206, n+ region 210, and n+ region 214 of the n-doped base 120. Portions of bottom sides and left or right sides of the two first STI regions 216a abut the n-doped well 206, n+ region 210, and/or n+ region 214 of the n-doped base 120. In addition, a first STI region 216a contacting an n-doped base 120 may also contact a p-doped well 204, a p+ region 208, and a p+ region 212 of an adjacent p-doped collector 124 on an opposite side of the first STI region 216a. Depending on location, portions of a bottom side and of a left or right side of the first STI region 216a abut the p-doped well 204, p+ region 208, and/or p+ region 212 of the adjacent p-doped collector 124.

In the example implementation 704, an RPO structure 218 may partially overlap a p-doped well 204 of a p-doped collector 124, and a p+ region 208 of a p-doped collector 124, and partially overlap a second STI region 216b, where the second STI region 216b is in contact with a p-doped well 204 of the p-doped collector 124, and an n-doped well 206, an n+ region 210, and a p+ region 212 of a p-doped emitter 122. A bottom and/or a first lateral side (e.g., left or right side) of the second STI region 216b is in contact with (e.g., abuts) a p-doped well 204 of the p-doped collector 124. A bottom and/or second lateral side (e.g., left or right side) of the second STI region 216b is in contact with (e.g., abuts) an n-doped well 206, an n+ region 210, and/or a p+ region 212 of the p-doped emitter 122. An RPO structure 218 also overlaps a space between an edge of a second STI region 216b and an edge of a p+ region 208 of an adjacent p-doped collector 124, where the space is occupied by part of the p-doped well 204. As can be seen, an RPO structure 218 also overlaps a space between an edge of a second STI region 216b and an edge of a p+ region 212 of an adjacent p-doped collector 124, where the space is occupied by parts of the p-doped well 204 and of the p+ region 208.

In the example implementation 704 in FIG. 7B, the ESD triggering circuit 106 includes 3 “fingers” of PNP ESD triggering devices 118 including 2 n-doped bases 120, 4 p-doped collectors 124, and 3 p-doped emitters 122.

FIG. 7B illustrates a plurality of example dimensions of the example implementation 704 of the ESD triggering circuit 106. In some implementations, one or more other example implementations of ESD triggering circuits 106 described herein may include one or more of the example dimensions illustrated and described in connection with FIG. 7B.

An example dimension D20 includes a lateral extension of an n-doped barrier layer 702 from an outer edge of an n-doped well 206 over the n-doped barrier layer 702. In some implementations, the example dimension D20 may be included in a range of approximately −5 micrometers (meaning that the n-doped barrier layer 702 does not laterally extend outward from the outer edge of the n-doped well 206) to approximately 5 micrometers. If the example dimension D20 is less than approximately −5 micrometers, the n-doped barrier layer 702 may not provide sufficient blocking of charge carrier migration into the substrate 202, resulting in reduced electrical isolation and reduced operating efficiency in the ESD triggering circuit 106. If the example dimension D20 is greater than approximately 5 micrometers, the breakdown voltage of the ESD triggering circuit 106 may be too low to enable high voltage operation of the associated device circuit 102 (e.g., less than the operating voltage of the associated device circuit 102). However, other values for the range are within the scope of the present disclosure.

An example dimension D21 includes a distance or spacing in the x-direction between an edge of a second STI region 216b and an edge of a p+ region 208 of a p-doped collector 124. In some implementations, the example dimension D21 may be included in a range of approximately 0.3 micrometers to approximately 4 micrometers. If the example dimension D21 is less than approximately 0.3 micrometers, the second STI region 216b will not be sufficiently spaced apart from a p+ region 208 of an adjacent p-doped collector 124 to allow for charge carrier movement to the p-doped collector 124. In other words, if the second STI region 216b is too close to the p+ region 208 of an adjacent p-doped collector 124, the second STI region 216b may obstruct movement of charge carriers (e.g., holes) to the p-doped collectors 124 from the interfaces 706 between the p-doped collectors 124 and p-doped emitters 122. The blocking of charge carrier movement may cause high on resistance (Rₒₙ) for an ESD triggering circuit 106, which may lead to reduced operating efficiency for the ESD triggering circuit 106, or failure of ESD devices and functional devices during ESD events. If the example dimension D21 is greater than approximately 4 micrometers, the lateral size of the ESD triggering circuit 106 may increase, thereby reducing device density in the semiconductor device. However, other values for the range are within the scope of the present disclosure.

As indicated above, FIGS. 7A and 7B are provided as an example. Other examples may differ from what is described with regard to FIGS. 7A and 7B.

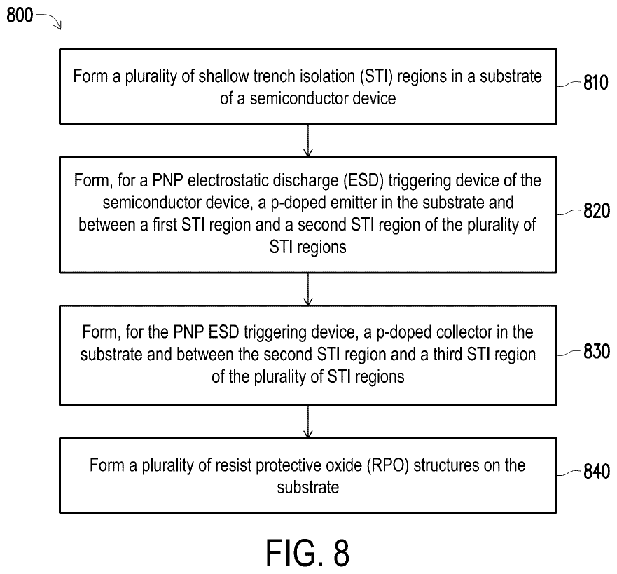

FIG. 8 is a flowchart of an example process 800 associated with forming a semiconductor device. In some implementations, one or more process blocks of FIG. 8 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 8, process 800 may include forming a plurality of shallow trench isolation (STI) regions in a substrate of a semiconductor device (block 810). For example, one or more semiconductor processing tools may be used to form a plurality of shallow trench isolation (STI) regions (e.g., second STI regions 216b) in a substrate (e.g., substrate 202) of a semiconductor device (e.g., semiconductor device 100, 126, 128), as described herein.

As further shown in FIG. 8, process 800 may include forming, for a PNP electrostatic discharge (ESD) triggering device of the semiconductor device, a p-doped emitter in the substrate and between a first STI region and a second STI region of the plurality of STI regions (block 820). For example, one or more semiconductor processing tools may be used to form, for a PNP electrostatic discharge (ESD) triggering device (e.g., PNP ESD triggering device 118) of the semiconductor device, a p-doped emitter (e.g., p-doped emitter 122) in the substrate and between a first STI region and a second STI region of the plurality of STI regions, as described herein. In some implementations, the first STI region and the second STI region abut a plurality of doped regions of the p-doped emitter.

As further shown in FIG. 8, process 800 may include forming, for the PNP ESD triggering device, a p-doped collector in the substrate and between the second STI region and a third STI region of the plurality of STI regions (block 830). For example, one or more semiconductor processing tools may be used to form, for the PNP ESD triggering device, a p-doped collector (e.g., p-doped collector 124) in the substrate and between the second STI region and a third STI region of the plurality of STI regions, as described herein. In some implementations, the second STI region and the third STI region are spaced apart from one or more doped regions of the p-doped collector.

As further shown in FIG. 8, process 800 may include forming a plurality of resist protective oxide (RPO) structures on the substrate (block 840). For example, one or more semiconductor processing tools may be used to form a plurality of resist protective oxide (RPO) structures (e.g., RPO structures 218) on the substrate, as described herein. In some implementations, a first RPO structure of the plurality of RPO structures partially overlaps the first STI region. In some implementations, a second RPO structure of the plurality of RPO structures partially overlaps the second STI region. In some implementations, a third RPO structure of the plurality of RPO structures partially overlaps the third STI region.

Process 800 may include additional implementations, such as any single implementation or any combination of implementations described below and/or in connection with one or more other processes described elsewhere herein.

In a first implementation, the second RPO structure partially overlaps at least one doped region of the plurality of doped regions of the p-doped emitter, where the second RPO structure partially overlaps the one or more doped regions of the p-doped collector.

In a second implementation, alone or in combination with the first implementation, the second RPO structure overlaps a first space between an edge of the second STI region and the one or more doped regions of the p-doped collector, and the third RPO structure overlaps a second space between an edge of the third STI region and the one or more doped regions of the p-doped collector.

In a third implementation, alone or in combination with one or more of the first and second implementations, a first portion of the substrate is in the first space, and a second portion of the substrate is in the second space.

In a fourth implementation, alone or in combination with one or more of the first through third implementations, the first space is on a first side of the p-doped collector, and the second space is on a second side of the p-doped collector opposite the first side.

In a fifth implementation, alone or in combination with one or more of the first through fourth implementations, process 800 includes forming, for the PNP ESD triggering device, an additional p-doped emitter in the substrate, and the additional p-doped emitter is formed between the third STI region and a fourth STI region of the plurality of STI regions, where the third STI region and the fourth STI region abut a plurality of doped regions of the p-doped emitter.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

In this way, a semiconductor device includes a high voltage ESD triggering device that includes a combination of isolation regions (e.g., STI regions), and RPO structures over doped regions of a substrate. The RPO structures partially overlap STI regions in areas between doped collectors and doped emitters of a high voltage ESD triggering device. The STI regions which are partially overlapped by the RPO structures have smaller widths than STI regions that are not overlapped by the RPO structures. The smaller dimensions allow for unobstructed movement of charge carriers (e.g., holes) from areas between the doped collectors and doped emitters to the doped collectors. As a result, Rₒₙ is reduced in comparison to the Rₒₙ for high voltage ESD triggering devices with other isolation region arrangements. Additionally, the inclusion of the combination of isolation regions preserves BV, leading to increased operating efficiency and performance for high voltage ESD triggering devices including the noted isolation region and RPO structure arrangements.

As described in greater detail above, some implementations described herein provide a semiconductor device. The semiconductor device includes a device circuit. The semiconductor device includes an electrostatic discharge (ESD) circuit coupled to the device circuit. The semiconductor device includes an ESD triggering circuit, coupled to the ESD circuit and the device circuit, and including a substrate, and a PNP ESD triggering device, in the substrate. The PNP ESD triggering device includes a p-doped collector including a first plurality of doped regions, and a p-doped emitter including a second plurality of doped regions. The PNP ESD triggering device includes a shallow trench isolation (STI) region in the substrate and between the p-doped collector and p-doped emitter, where the STI region is in contact with the second plurality of doped regions and is spaced apart from one or more of the first plurality of doped regions. The PNP ESD triggering device includes a resist protective oxide (RPO) structure on the substrate, where the RPO structure is over a portion of the p-doped collector, over a portion of the p-doped emitter, and over a portion of the STI region.

As described in greater detail above, some implementations described herein provide a method. The method includes forming a plurality of shallow trench isolation (STI) regions in a substrate of a semiconductor device. The method includes forming, for a PNP electrostatic discharge (ESD) triggering device of the semiconductor device, a p-doped emitter in the substrate and between a first STI region and a second STI region of the plurality of STI regions, where the first STI region and the second STI region abut a plurality of doped regions of the p-doped emitter. The method includes forming, for the PNP ESD triggering device, a p-doped collector in the substrate and between the second STI region and a third STI region of the plurality of STI regions, where the second STI region and the third STI region are spaced apart from one or more doped regions of the p-doped collector. The method includes forming a plurality of resist protective oxide (RPO) structures on the substrate, where a first RPO structure of the plurality of RPO structures partially overlaps the first STI region, where a second RPO structure of the plurality of RPO structures partially overlaps the second STI region, and where a third RPO structure of the plurality of RPO structures partially overlaps the third STI region.

As described in greater detail above, some implementations described herein provide a semiconductor device. The semiconductor device includes a substrate. The semiconductor device includes a first plurality of shallow trench isolation (STI) regions in the substrate. The semiconductor device includes a second plurality of STI regions in the substrate, where the first plurality of STI regions have a larger dimension in a lateral direction along a top surface of the substrate than a dimension of the second plurality of STI regions in the lateral direction. The semiconductor device includes a first doped structure in the substrate and between a first STI region of the first plurality of STI regions and a second STI region of the first plurality of STI regions. The semiconductor device includes a second doped structure in the substrate and between the second STI region of the first plurality of STI regions and a first STI region of the second plurality of STI regions, where the second doped structure includes a doped well, and one or more doped regions in the doped well, and where the first STI region of the second plurality of STI regions is spaced apart from the one or more doped regions. The semiconductor device includes a third doped structure in the substrate and between the first STI region of the second plurality of STI regions and a second STI region of the second plurality of STI regions, where the third doped structure includes a plurality of doped regions, and where the first STI region of the second plurality of STI regions and the second STI region of the second plurality of STI regions are in contact with the plurality of doped regions. The semiconductor device includes a plurality of resist protective oxide (RPO) structures on the substrate, where an RPO structure of the plurality of RPO structures is over a portion of the second doped structure and over a portion of a space between the first STI region of the second plurality of STI regions and the one or more doped regions.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a device circuit;
an electrostatic discharge (ESD) circuit coupled to the device circuit; and
an ESD triggering circuit, coupled to the ESD circuit and the device circuit, comprising:
a substrate;
a PNP ESD triggering device, in the substrate, comprising:
a p-doped collector comprising a first plurality of doped regions; and
a p-doped emitter comprising a second plurality of doped regions;
a shallow trench isolation (STI) region in the substrate and between the p-doped collector and p-doped emitter,
wherein the STI region is in contact with the second plurality of doped regions and is spaced apart from one or more of the first plurality of doped regions; and
a resist protective oxide (RPO) structure on the substrate,
wherein the RPO structure is over a portion of the p-doped collector, over a portion of the p-doped emitter, and over a portion of the STI region.

2. The semiconductor device of claim 1, wherein the first plurality of doped regions comprise a p-doped well, a first p-type region in the p-doped well, and a second p-type region in the first p-type region, and
wherein the STI region is spaced apart from the first p-type region and the second p-type region.

3. The semiconductor device of claim 2, wherein a portion of the p-doped well is located in a space between an edge of the STI region and an edge of the first p-type region.

4. The semiconductor device of claim 2, wherein a portion of an edge of the STI region is spaced apart from the p-doped well.

5. The semiconductor device of claim 4, wherein a portion of the substrate is located in a space between the portion of the edge of the STI region and an edge of the p-doped well.

6. The semiconductor device of claim 2, wherein the RPO structure is over the p-doped well and the first p-type region.

7. The semiconductor device of claim 1, wherein the second plurality of doped regions comprise an n-doped well, an n-type region in the n-doped well, and a p-type region in the n-type region, and
wherein the RPO structure is over the n-doped well and the n-type region.

8. The semiconductor device of claim 1, wherein a portion of the substrate is located in a space between an edge of the STI region and the one or more of the first plurality of doped regions.

9. A method, comprising:
forming a plurality of shallow trench isolation (STI) regions in a substrate of a semiconductor device;
forming, for a PNP electrostatic discharge (ESD) triggering device of the semiconductor device, a p-doped emitter in the substrate and between a first STI region and a second STI region of the plurality of STI regions,
wherein the first STI region and the second STI region abut a plurality of doped regions of the p-doped emitter;
forming, for the PNP ESD triggering device, a p-doped collector in the substrate and between the second STI region and a third STI region of the plurality of STI regions,
wherein the second STI region and the third STI region are spaced apart from one or more doped regions of the p-doped collector; and
forming a plurality of resist protective oxide (RPO) structures on the substrate,
wherein a first RPO structure of the plurality of RPO structures partially overlaps the first STI region,
wherein a second RPO structure of the plurality of RPO structures partially overlaps the second STI region, and
wherein a third RPO structure of the plurality of RPO structures partially overlaps the third STI region.

10. The method of claim 9, wherein the second RPO structure partially overlaps at least one doped region of the plurality of doped regions of the p-doped emitter, and
wherein the second RPO structure partially overlaps the one or more doped regions of the p-doped collector.

11. The method of claim 9, wherein the second RPO structure overlaps a first space between an edge of the second STI region and the one or more doped regions of the p-doped collector, and
wherein the third RPO structure overlaps a second space between an edge of the third STI region and the one or more doped regions of the p-doped collector.

12. The method of claim 11, wherein a first portion of the substrate is in the first space, and wherein a second portion of the substrate is in the second space.

13. The method of claim 11, wherein the first space is on a first side of the p-doped collector, and
wherein the second space is on a second side of the p-doped collector opposite the first side.

14. The method of claim 9, further comprising forming, for the PNP ESD triggering device, an additional p-doped emitter in the substrate,
wherein the additional p-doped emitter is formed between the third STI region and a fourth STI region of the plurality of STI regions, and
wherein the third STI region and the fourth STI region abut a plurality of doped regions of the p-doped emitter.

15. A semiconductor device, comprising:
a substrate;
a first plurality of shallow trench isolation (STI) regions in the substrate;
a second plurality of STI regions in the substrate,
wherein the first plurality of STI regions have a larger dimension in a lateral direction along a top surface of the substrate than a dimension of the second plurality of STI regions in the lateral direction;
a first doped structure in the substrate and between a first STI region of the first plurality of STI regions and a second STI region of the first plurality of STI regions;
a second doped structure in the substrate and between the second STI region of the first plurality of STI regions and a first STI region of the second plurality of STI regions,
wherein the second doped structure comprises a doped well, and one or more doped regions in the doped well, and
wherein the first STI region of the second plurality of STI regions is spaced apart from the one or more doped regions;
a third doped structure in the substrate and between the first STI region of the second plurality of STI regions and a second STI region of the second plurality of STI regions,
wherein the third doped structure comprises a plurality of doped regions, and
wherein the first STI region of the second plurality of STI regions and the second STI region of the second plurality of STI regions are in contact with the plurality of doped regions; and
a plurality of resist protective oxide (RPO) structures on the substrate,
wherein an RPO structure of the plurality of RPO structures is over a portion of the second doped structure and over a portion of a space between the first STI region of the second plurality of STI regions and the one or more doped regions.

16. The semiconductor device of claim 15, wherein the dimension of the second plurality of STI regions is included in a range of approximately 2 micrometers to approximately 7 micrometers.

17. The semiconductor device of claim 15, wherein a distance between an edge of the first STI region of the second plurality of STI regions and an edge of a doped region of the one or more doped regions is included in a range of approximately 0.3 micrometers to approximately 4 micrometers.

18. The semiconductor device of claim 15, wherein the RPO structure overlaps part of the first STI region.

19. The semiconductor device of claim 15, further comprising:
a first doped barrier region in the substrate and under the first doped structure; and
a second doped barrier region in the substrate and under the third doped structure,
wherein the first and second doped barrier regions are spaced apart from each other and arranged in the lateral direction.

20. The semiconductor device of claim 19, further comprising a deep doped barrier layer under at least one of the first and second doped barrier regions.
